SEQUENCE LISTING (105 sequences)

SEQ ID NO: 1 - protein, 45 aa, synthetic construct
  REGION 1..45: note = Description of sequence: component of rubredoxin polypeptide
MQKYVCNVCGYEYDPAEHDNVPFDQLPDDWCCPVCGVSKDQFSPA

SEQ ID NO: 2 - protein, 53 aa, synthetic construct
  REGION 1..53: note = Description of sequence: component of rubredoxin polypeptide
MQKYVCDICGYVYDPEVGDPDGGINPGTAFEDIPEDWVCPLCGVGKEDFSPED

SEQ ID NO: 3 - protein, 54 aa, synthetic construct
  REGION 1..54: note = Description of sequence: component of rubredoxin polypeptide
MKRYECIVCGWIYDEELGCPEEGIAPGTKWDDIPDDWTCPECGVGKLDFEMMEV

SEQ ID NO: 4 - protein, 55 aa, synthetic construct
  REGION 1..55: note = Description of sequence: component of rubredoxin polypeptide
MIEMARYQCMCGWVYDEDKGEPSQNIPPGTKFEDLPDTFRCPQCGLGKNAFRKID

SEQ ID NO: 5 - protein, 54 aa, synthetic construct
  REGION 1..54: note = Description of sequence: component of rubredoxin polypeptide
MAKWVCKICGYIYDEDAGDPDNGISPGTKFEELPDDWVCPICGAPKSEFEKLED

SEQ ID NO: 6 - protein, 45 aa, synthetic construct
  REGION 1..45: note = Description of sequence: component of rubredoxin polypeptide
MQKYVHNVCGYEYDPAEHDNVPFDQLPDDWCCPVCGVSKDQFSPA

SEQ ID NO: 7 - protein, 53 aa, synthetic construct
  REGION 1..53: note = Description of sequence: component of rubredoxin polypeptide
MQKYVHDICGYVYDPEVGDPDGGINPGTAFEDIPEDWVCPLCGVGKEDFSPED

SEQ ID NO: 8 - protein, 54 aa, synthetic construct
  REGION 1..54: note = Description of sequence: component of rubredoxin polypeptide
MKRYEHIVCGWIYDEELGCPEEGIAPGTKWDDIPDDWTCPECGVGKLDFEMMEV

SEQ ID NO: 9 - protein, 55 aa, synthetic construct
  REGION 1..55: note = Description of sequence: component of rubredoxin polypeptide
MIEMARYQHMCGWVYDEDKGEPSQNIPPGTKFEDLPDTFRCPQCGLGKNAFRKID

SEQ ID NO: 10 - protein, 54 aa, synthetic construct
  REGION 1..54: note = Description of sequence: component of rubredoxin polypeptide
MAKWVHKICGYIYDEDAGDPDNGISPGTKFEELPDDWVCPICGAPKSEFEKLED

SEQ ID NO: 11 - protein, 45 aa, synthetic construct
  REGION 1..45: note = Description of sequence: component of rubredoxin polypeptide
MQKYVCNVHGYEYDPAEHDNVPFDQLPDDWCCPVCGVSKDQFSPA

SEQ ID NO: 12 - protein, 53 aa, synthetic construct
  REGION 1..53: note = Description of sequence: component of rubredoxin polypeptide
MQKYVCDIHGYVYDPEVGDPDGGINPGTAFEDIPEDWVCPLCGVGKEDFSPED

SEQ ID NO: 13 - protein, 54 aa, synthetic construct
  REGION 1..54: note = Description of sequence: component of rubredoxin polypeptide
MKRYECIVHGWIYDEELGCPEEGIAPGTKWDDIPDDWTCPECGVGKLDFEMMEV

SEQ ID NO: 14 - protein, 55 aa, synthetic construct
  REGION 1..55: note = Description of sequence: component of rubredoxin polypeptide
MIEMARYQCMHGWVYDEDKGEPSQNIPPGTKFEDLPDTFRCPQCGLGKNAFRKID

SEQ ID NO: 15 - protein, 54 aa, synthetic construct
  REGION 1..54: note = Description of sequence: component of rubredoxin polypeptide
MAKWVCKIHGYIYDEDAGDPDNGISPGTKFEELPDDWVCPICGAPKSEFEKLED

SEQ ID NO: 16 - protein, 45 aa, synthetic construct
  REGION 1..45: note = Description of sequence: component of rubredoxin polypeptide
MQKYVCNVCGYEYDPAEHDNVPFDQLPDDWCHPVCGVSKDQFSPA

SEQ ID NO: 17 - protein, 53 aa, synthetic construct
  REGION 1..53: note = Description of sequence: component of rubredoxin polypeptide
MQKYVCDICGYVYDPEVGDPDGGINPGTAFEDIPEDWVHPLCGVGKEDFSPED

SEQ ID NO: 18 - protein, 54 aa, synthetic construct
  REGION 1..54: note = Description of sequence: component of rubredoxin polypeptide
MKRYECIVCGWIYDEELGCPEEGIAPGTKWDDIPDDWTHPECGVGKLDFEMMEV

SEQ ID NO: 19 - protein, 55 aa, synthetic construct
  REGION 1..55: note = Description of sequence: component of rubredoxin polypeptide
MIEMARYQCMCGWVYDEDKGEPSQNIPPGTKFEDLPDTFRHPQCGLGKNAFRKID

SEQ ID NO: 20 - protein, 54 aa, synthetic construct
  REGION 1..54: note = Description of sequence: component of rubredoxin polypeptide
MAKWVCKICGYIYDEDAGDPDNGISPGTKFEELPDDWVHPICGAPKSEFEKLED

SEQ ID NO: 21 - protein, 45 aa, synthetic construct
  REGION 1..45: note = Description of sequence: component of rubredoxin polypeptide
MQKYVCNVCGYEYDPAEHDNVPFDQLPDDWCCPVHGVSKDQFSPA

SEQ ID NO: 22 - protein, 53 aa, synthetic construct
  REGION 1..53: note = Description of sequence: component of rubredoxin polypeptide
MQKYVCDICGYVYDPEVGDPDGGINPGTAFEDIPEDWVCPLHGVGKEDFSPED

SEQ ID NO: 23 - protein, 54 aa, synthetic construct
  REGION 1..54: note = Description of sequence: component of rubredoxin polypeptide
MKRYECIVCGWIYDEELGCPEEGIAPGTKWDDIPDDWTCPEHGVGKLDFEMMEV

SEQ ID NO: 24 - protein, 55 aa, synthetic construct
  REGION 1..55: note = Description of sequence: component of rubredoxin polypeptide
MIEMARYQCMCGWVYDEDKGEPSQNIPPGTKFEDLPDTFRCPQHGLGKNAFRKID

SEQ ID NO: 25 - protein, 54 aa, synthetic construct
  REGION 1..54: note = Description of sequence: component of rubredoxin polypeptide
MAKWVCKICGYIYDEDAGDPDNGISPGTKFEELPDDWVCPIHGAPKSEFEKLED

SEQ ID NO: 26 - protein, 45 aa, synthetic construct
  REGION 1..45: note = Description of sequence: component of rubredoxin polypeptide
MQKYVDNVCGYEYDPAEHDNVPFDQLPDDWCCPVCGVSKDQFSPA

SEQ ID NO: 27 - protein, 53 aa, synthetic construct
  REGION 1..53: note = Description of sequence: component of rubredoxin polypeptide
MQKYVDDICGYVYDPEVGDPDGGINPGTAFEDIPEDWVCPLCGVGKEDFSPED

SEQ ID NO: 28 - protein, 54 aa, synthetic construct
  REGION 1..54: note = Description of sequence: component of rubredoxin polypeptide
MKRYEDIVCGWIYDEELGCPEEGIAPGTKWDDIPDDWTCPECGVGKLDFEMMEV

SEQ ID NO: 29 - protein, 55 aa, synthetic construct
  REGION 1..55: note = Description of sequence: component of rubredoxin polypeptide
MIEMARYQDMCGWVYDEDKGEPSQNIPPGTKFEDLPDTFRCPQCGLGKNAFRKID

SEQ ID NO: 30 - protein, 54 aa, synthetic construct
  REGION 1..54: note = Description of sequence: component of rubredoxin polypeptide
MAKWVDKICGYIYDEDAGDPDNGISPGTKFEELPDDWVCPICGAPKSEFEKLED

SEQ ID NO: 31 - protein, 45 aa, synthetic construct
  REGION 1..45: note = Description of sequence: component of rubredoxin polypeptide
MQKYVCNVDGYEYDPAEHDNVPFDQLPDDWCCPVCGVSKDQFSPA

SEQ ID NO: 32 - protein, 53 aa, synthetic construct
  REGION 1..53: note = Description of sequence: component of rubredoxin polypeptide
MQKYVCDIDGYVYDPEVGDPDGGINPGTAFEDIPEDWVCPLCGVGKEDFSPED

SEQ ID NO: 33 - protein, 54 aa, synthetic construct
  REGION 1..54: note = Description of sequence: component of rubredoxin polypeptide
MKRYECIVDGWIYDEELGCPEEGIAPGTKWDDIPDDWTCPECGVGKLDFEMMEV

SEQ ID NO: 34 - protein, 55 aa, synthetic construct
  REGION 1..55: note = Description of sequence: component of rubredoxin polypeptide
MIEMARYQCMDGWVYDEDKGEPSQNIPPGTKFEDLPDTFRCPQCGLGKNAFRKID

SEQ ID NO: 35 - protein, 54 aa, synthetic construct
  REGION 1..54: note = Description of sequence: component of rubredoxin polypeptide
MAKWVCKIDGYIYDEDAGDPDNGISPGTKFEELPDDWVCPICGAPKSEFEKLED

SEQ ID NO: 36 - protein, 45 aa, synthetic construct
  REGION 1..45: note = Description of sequence: component of rubredoxin polypeptide
MQKYVCNVCGYEYDPAEHDNVPFDQLPDDWCDPVCGVSKDQFSPA

SEQ ID NO: 37 - protein, 53 aa, synthetic construct
  REGION 1..53: note = Description of sequence: component of rubredoxin polypeptide
MQKYVCDICGYVYDPEVGDPDGGINPGTAFEDIPEDWVDPLCGVGKEDFSPED

SEQ ID NO: 38 - protein, 54 aa, synthetic construct
  REGION 1..54: note = Description of sequence: component of rubredoxin polypeptide
MKRYECIVCGWIYDEELGCPEEGIAPGTKWDDIPDDWTDPECGVGKLDFEMMEV

SEQ ID NO: 39 - protein, 55 aa, synthetic construct
  REGION 1..55: note = Description of sequence: component of rubredoxin polypeptide
MIEMARYQCMCGWVYDEDKGEPSQNIPPGTKFEDLPDTFRDPQCGLGKNAFRKID

SEQ ID NO: 40 - protein, 54 aa, synthetic construct
  REGION 1..54: note = Description of sequence: component of rubredoxin polypeptide
MAKWVCKICGYIYDEDAGDPDNGISPGTKFEELPDDWVDPICGAPKSEFEKLED

SEQ ID NO: 41 - protein, 45 aa, synthetic construct
  REGION 1..45: note = Description of sequence: component of rubredoxin polypeptide
MQKYVCNVCGYEYDPAEHDNVPFDQLPDDWCCPVDGVSKDQFSPA

SEQ ID NO: 42 - protein, 53 aa, synthetic construct
  REGION 1..53: note = Description of sequence: component of rubredoxin polypeptide
MQKYVCDICGYVYDPEVGDPDGGINPGTAFEDIPEDWVCPLDGVGKEDFSPED

SEQ ID NO: 43 - protein, 54 aa, synthetic construct
  REGION 1..54: note = Description of sequence: component of rubredoxin polypeptide
MKRYECIVCGWIYDEELGCPEEGIAPGTKWDDIPDDWTCPEDGVGKLDFEMMEV

SEQ ID NO: 44 - protein, 55 aa, synthetic construct
  REGION 1..55: note = Description of sequence: component of rubredoxin polypeptide
MIEMARYQCMCGWVYDEDKGEPSQNIPPGTKFEDLPDTFRCPQDGLGKNAFRKID

SEQ ID NO: 45 - protein, 54 aa, synthetic construct
  REGION 1..54: note = Description of sequence: component of rubredoxin polypeptide
MAKWVCKICGYIYDEDAGDPDNGISPGTKFEELPDDWVCPIDGAPKSEFEKLED

SEQ ID NO: 46 - protein, 45 aa, synthetic construct
  REGION 1..45: note = Description of sequence: component of rubredoxin polypeptide
MQKYVENVCGYEYDPAEHDNVPFDQLPDDWCCPVCGVSKDQFSPA

SEQ ID NO: 47 - protein, 53 aa, synthetic construct
  REGION 1..53: note = Description of sequence: component of rubredoxin polypeptide
MQKYVEDICGYVYDPEVGDPDGGINPGTAFEDIPEDWVCPLCGVGKEDFSPED

SEQ ID NO: 48 - protein, 54 aa, synthetic construct
  REGION 1..54: note = Description of sequence: component of rubredoxin polypeptide
MKRYEEIVCGWIYDEELGCPEEGIAPGTKWDDIPDDWTCPECGVGKLDFEMMEV

SEQ ID NO: 49 - protein, 55 aa, synthetic construct
  REGION 1..55: note = Description of sequence: component of rubredoxin polypeptide
MIEMARYQEMCGWVYDEDKGEPSQNIPPGTKFEDLPDTFRCPQCGLGKNAFRKID

SEQ ID NO: 50 - protein, 54 aa, synthetic construct
  REGION 1..54: note = Description of sequence: component of rubredoxin polypeptide
MAKWVEKICGYIYDEDAGDPDNGISPGTKFEELPDDWVCPICGAPKSEFEKLED

SEQ ID NO: 51 - protein, 45 aa, synthetic construct
  REGION 1..45: note = Description of sequence: component of rubredoxin polypeptide
MQKYVCNVEGYEYDPAEHDNVPFDQLPDDWCCPVCGVSKDQFSPA

SEQ ID NO: 52 - protein, 53 aa, synthetic construct
  REGION 1..53: note = Description of sequence: component of rubredoxin polypeptide
MQKYVCDIEGYVYDPEVGDPDGGINPGTAFEDIPEDWVCPLCGVGKEDFSPED

SEQ ID NO: 53 - protein, 54 aa, synthetic construct
  REGION 1..54: note = Description of sequence: component of rubredoxin polypeptide
MKRYECIVEGWIYDEELGCPEEGIAPGTKWDDIPDDWTCPECGVGKLDFEMMEV

SEQ ID NO: 54 - protein, 55 aa, synthetic construct
  REGION 1..55: note = Description of sequence: component of rubredoxin polypeptide
MIEMARYQCMEGWVYDEDKGEPSQNIPPGTKFEDLPDTFRCPQCGLGKNAFRKID

SEQ ID NO: 55 - protein, 54 aa, synthetic construct
  REGION 1..54: note = Description of sequence: component of rubredoxin polypeptide
MAKWVCKIEGYIYDEDAGDPDNGISPGTKFEELPDDWVCPICGAPKSEFEKLED

SEQ ID NO: 56 - protein, 45 aa, synthetic construct
  REGION 1..45: note = Description of sequence: component of rubredoxin polypeptide
MQKYVCNVCGYEYDPAEHDNVPFDQLPDDWCEPVCGVSKDQFSPA

SEQ ID NO: 57 - protein, 53 aa, synthetic construct
  REGION 1..53: note = Description of sequence: component of rubredoxin polypeptide
MQKYVCDICGYVYDPEVGDPDGGINPGTAFEDIPEDWVEPLCGVGKEDFSPED

SEQ ID NO: 58 - protein, 54 aa, synthetic construct
  REGION 1..54: note = Description of sequence: component of rubredoxin polypeptide
MKRYECIVCGWIYDEELGCPEEGIAPGTKWDDIPDDWTEPECGVGKLDFEMMEV

SEQ ID NO: 59 - protein, 55 aa, synthetic construct
  REGION 1..55: note = Description of sequence: component of rubredoxin polypeptide
MIEMARYQCMCGWVYDEDKGEPSQNIPPGTKFEDLPDTFREPQCGLGKNAFRKID

SEQ ID NO: 60 - protein, 54 aa, synthetic construct
  REGION 1..54: note = Description of sequence: component of rubredoxin polypeptide
MAKWVCKICGYIYDEDAGDPDNGISPGTKFEELPDDWVEPICGAPKSEFEKLED

SEQ ID NO: 61 - protein, 45 aa, synthetic construct
  REGION 1..45: note = Description of sequence: component of rubredoxin polypeptide
MQKYVCNVCGYEYDPAEHDNVPFDQLPDDWCCPVEGVSKDQFSPA

SEQ ID NO: 62 - protein, 53 aa, synthetic construct
  REGION 1..53: note = Description of sequence: component of rubredoxin polypeptide
MQKYVCDICGYVYDPEVGDPDGGINPGTAFEDIPEDWVCPLEGVGKEDFSPED

SEQ ID NO: 63 - protein, 54 aa, synthetic construct
  REGION 1..54: note = Description of sequence: component of rubredoxin polypeptide
MKRYECIVCGWIYDEELGCPEEGIAPGTKWDDIPDDWTCPEEGVGKLDFEMMEV

SEQ ID NO: 64 - protein, 55 aa, synthetic construct
  REGION 1..55: note = Description of sequence: component of rubredoxin polypeptide
MIEMARYQCMCGWVYDEDKGEPSQNIPPGTKFEDLPDTFRCPQEGLGKNAFRKID

SEQ ID NO: 65 - protein, 54 aa, synthetic construct
  REGION 1..54: note = Description of sequence: component of rubredoxin polypeptide
MAKWVCKICGYIYDEDAGDPDNGISPGTKFEELPDDWVCPIEGAPKSEFEKLED

SEQ ID NO: 66 - protein, 45 aa, synthetic construct
  REGION 1..45: note = Description of sequence: component of rubredoxin polypeptide
MQKYVSNVCGYEYDPAEHDNVPFDQLPDDWCCPVCGVSKDQFSPA

SEQ ID NO: 67 - protein, 53 aa, synthetic construct
  REGION 1..53: note = Description of sequence: component of rubredoxin polypeptide
MQKYVSDICGYVYDPEVGDPDGGINPGTAFEDIPEDWVCPLCGVGKEDFSPED

SEQ ID NO: 68 - protein, 54 aa, synthetic construct
  REGION 1..54: note = Description of sequence: component of rubredoxin polypeptide
MKRYESIVCGWIYDEELGCPEEGIAPGTKWDDIPDDWTCPECGVGKLDFEMMEV

SEQ ID NO: 69 - protein, 55 aa, synthetic construct
  REGION 1..55: note = Description of sequence: component of rubredoxin polypeptide
MIEMARYQSMCGWVYDEDKGEPSQNIPPGTKFEDLPDTFRCPQCGLGKNAFRKID

SEQ ID NO: 70 - protein, 54 aa, synthetic construct
  REGION 1..54: note = Description of sequence: component of rubredoxin polypeptide
MAKWVSKICGYIYDEDAGDPDNGISPGTKFEELPDDWVCPICGAPKSEFEKLED

SEQ ID NO: 71 - protein, 45 aa, synthetic construct
  REGION 1..45: note = Description of sequence: component of rubredoxin polypeptide
MQKYVCNVSGYEYDPAEHDNVPFDQLPDDWCCPVCGVSKDQFSPA

SEQ ID NO: 72 - protein, 53 aa, synthetic construct
  REGION 1..53: note = Description of sequence: component of rubredoxin polypeptide
MQKYVCDISGYVYDPEVGDPDGGINPGTAFEDIPEDWVCPLCGVGKEDFSPED

SEQ ID NO: 73 - protein, 54 aa, synthetic construct
  REGION 1..54: note = Description of sequence: component of rubredoxin polypeptide
MKRYECIVSGWIYDEELGCPEEGIAPGTKWDDIPDDWTCPECGVGKLDFEMMEV

SEQ ID NO: 74 - protein, 55 aa, synthetic construct
  REGION 1..55: note = Description of sequence: component of rubredoxin polypeptide
MIEMARYQCMSGWVYDEDKGEPSQNIPPGTKFEDLPDTFRCPQCGLGKNAFRKID

SEQ ID NO: 75 - protein, 54 aa, synthetic construct
  REGION 1..54: note = Description of sequence: component of rubredoxin polypeptide
MAKWVCKISGYIYDEDAGDPDNGISPGTKFEELPDDWVCPICGAPKSEFEKLED

SEQ ID NO: 76 - protein, 45 aa, synthetic construct
  REGION 1..45: note = Description of sequence: component of rubredoxin polypeptide
MQKYVCNVCGYEYDPAEHDNVPFDQLPDDWCSPVCGVSKDQFSPA

SEQ ID NO: 77 - protein, 53 aa, synthetic construct
  REGION 1..53: note = Description of sequence: component of rubredoxin polypeptide
MQKYVCDICGYVYDPEVGDPDGGINPGTAFEDIPEDWVSPLCGVGKEDFSPED

SEQ ID NO: 78 - protein, 54 aa, synthetic construct
  REGION 1..54: note = Description of sequence: component of rubredoxin polypeptide
MKRYECIVCGWIYDEELGCPEEGIAPGTKWDDIPDDWTSPECGVGKLDFEMMEV

SEQ ID NO: 79 - protein, 55 aa, synthetic construct
  REGION 1..55: note = Description of sequence: component of rubredoxin polypeptide
MIEMARYQCMCGWVYDEDKGEPSQNIPPGTKFEDLPDTFRSPQCGLGKNAFRKID

SEQ ID NO: 80 - protein, 54 aa, synthetic construct
  REGION 1..54: note = Description of sequence: component of rubredoxin polypeptide
MAKWVCKICGYIYDEDAGDPDNGISPGTKFEELPDDWVSPICGAPKSEFEKLED

SEQ ID NO: 81 - protein, 45 aa, synthetic construct
  REGION 1..45: note = Description of sequence: component of rubredoxin polypeptide
MQKYVCNVCGYEYDPAEHDNVPFDQLPDDWCCPVSGVSKDQFSPA

SEQ ID NO: 82 - protein, 53 aa, synthetic construct
  REGION 1..53: note = Description of sequence: component of rubredoxin polypeptide
MQKYVCDICGYVYDPEVGDPDGGINPGTAFEDIPEDWVCPLSGVGKEDFSPED

SEQ ID NO: 83 - protein, 54 aa, synthetic construct
  REGION 1..54: note = Description of sequence: component of rubredoxin polypeptide
MKRYECIVCGWIYDEELGCPEEGIAPGTKWDDIPDDWTCPESGVGKLDFEMMEV

SEQ ID NO: 84 - protein, 55 aa, synthetic construct
  REGION 1..55: note = Description of sequence: component of rubredoxin polypeptide
MIEMARYQCMCGWVYDEDKGEPSQNIPPGTKFEDLPDTFRCPQSGLGKNAFRKID

SEQ ID NO: 85 - protein, 54 aa, synthetic construct
  REGION 1..54: note = Description of sequence: component of rubredoxin polypeptide
MAKWVCKICGYIYDEDAGDPDNGISPGTKFEELPDDWVCPISGAPKSEFEKLED

SEQ ID NO: 86 - protein, 45 aa, synthetic construct
  REGION 1..45: note = Description of sequence: component of rubredoxin polypeptide
MQKYVANVCGYEYDPAEHDNVPFDQLPDDWCCPVCGVSKDQFSPA

SEQ ID NO: 87 - protein, 53 aa, synthetic construct
  REGION 1..53: note = Description of sequence: component of rubredoxin polypeptide
MQKYVADICGYVYDPEVGDPDGGINPGTAFEDIPEDWVCPLCGVGKEDFSPED

SEQ ID NO: 88 - protein, 54 aa, synthetic construct
  REGION 1..54: note = Description of sequence: component of rubredoxin polypeptide
MKRYEAIVCGWIYDEELGCPEEGIAPGTKWDDIPDDWTCPECGVGKLDFEMMEV

SEQ ID NO: 89 - protein, 55 aa, synthetic construct
  REGION 1..55: note = Description of sequence: component of rubredoxin polypeptide
MIEMARYQAMCGWVYDEDKGEPSQNIPPGTKFEDLPDTFRCPQCGLGKNAFRKID

SEQ ID NO: 90 - protein, 54 aa, synthetic construct
  REGION 1..54: note = Description of sequence: component of rubredoxin polypeptide
MAKWVAKICGYIYDEDAGDPDNGISPGTKFEELPDDWVCPICGAPKSEFEKLED

SEQ ID NO: 91 - protein, 45 aa, synthetic construct
  REGION 1..45: note = Description of sequence: component of rubredoxin polypeptide
MQKYVCNVAGYEYDPAEHDNVPFDQLPDDWCCPVCGVSKDQFSPA

SEQ ID NO: 92 - protein, 53 aa, synthetic construct
  REGION 1..53: note = Description of sequence: component of rubredoxin polypeptide
MQKYVCDIAGYVYDPEVGDPDGGINPGTAFEDIPEDWVCPLCGVGKEDFSPED

SEQ ID NO: 93 - protein, 54 aa, synthetic construct
  REGION 1..54: note = Description of sequence: component of rubredoxin polypeptide
MKRYECIVAGWIYDEELGCPEEGIAPGTKWDDIPDDWTCPECGVGKLDFEMMEV

SEQ ID NO: 94 - protein, 55 aa, synthetic construct
  REGION 1..55: note = Description of sequence: component of rubredoxin polypeptide
MIEMARYQCMAGWVYDEDKGEPSQNIPPGTKFEDLPDTFRCPQCGLGKNAFRKID

SEQ ID NO: 95 - protein, 54 aa, synthetic construct
  REGION 1..54: note = Description of sequence: component of rubredoxin polypeptide
MAKWVCKIAGYIYDEDAGDPDNGISPGTKFEELPDDWVCPICGAPKSEFEKLED

SEQ ID NO: 96 - protein, 45 aa, synthetic construct
  REGION 1..45: note = Description of sequence: component of rubredoxin polypeptide
MQKYVCNVCGYEYDPAEHDNVPFDQLPDDWCAPVCGVSKDQFSPA

SEQ ID NO: 97 - protein, 53 aa, synthetic construct
  REGION 1..53: note = Description of sequence: component of rubredoxin polypeptide
MQKYVCDICGYVYDPEVGDPDGGINPGTAFEDIPEDWVAPLCGVGKEDFSPED

SEQ ID NO: 98 - protein, 54 aa, synthetic construct
  REGION 1..54: note = Description of sequence: component of rubredoxin polypeptide
MKRYECIVCGWIYDEELGCPEEGIAPGTKWDDIPDDWTAPECGVGKLDFEMMEV

SEQ ID NO: 99 - protein, 55 aa, synthetic construct
  REGION 1..55: note = Description of sequence: component of rubredoxin polypeptide
MIEMARYQCMCGWVYDEDKGEPSQNIPPGTKFEDLPDTFRAPQCGLGKNAFRKID

SEQ ID NO: 100 - protein, 54 aa, synthetic construct
  REGION 1..54: note = Description of sequence: component of rubredoxin polypeptide
MAKWVCKICGYIYDEDAGDPDNGISPGTKFEELPDDWVAPICGAPKSEFEKLED

SEQ ID NO: 101 - protein, 45 aa, synthetic construct
  REGION 1..45: note = Description of sequence: component of rubredoxin polypeptide
MQKYVCNVCGYEYDPAEHDNVPFDQLPDDWCCPVAGVSKDQFSPA

SEQ ID NO: 102 - protein, 53 aa, synthetic construct
  REGION 1..53: note = Description of sequence: component of rubredoxin polypeptide
MQKYVCDICGYVYDPEVGDPDGGINPGTAFEDIPEDWVCPLAGVGKEDFSPED

SEQ ID NO: 103 - protein, 54 aa, synthetic construct
  REGION 1..54: note = Description of sequence: component of rubredoxin polypeptide
MKRYECIVCGWIYDEELGCPEEGIAPGTKWDDIPDDWTCPEAGVGKLDFEMMEV

SEQ ID NO: 104 - protein, 55 aa, synthetic construct
  REGION 1..55: note = Description of sequence: component of rubredoxin polypeptide
MIEMARYQCMCGWVYDEDKGEPSQNIPPGTKFEDLPDTFRCPQAGLGKNAFRKID

SEQ ID NO: 105 - protein, 54 aa, synthetic construct
  REGION 1..54: note = Description of sequence: component of rubredoxin polypeptide
MAKWVCKICGYIYDEDAGDPDNGISPGTKFEELPDDWVCPIAGAPKSEFEKLED

(19) United States
(12) Patent Application Publication
(10) Pub. No.: US 2026/0320459 A1
(43) Pub. Date: Oct. 15, 2026

(54) METALLOPROTEINS AS A TUNABLE SCAFFOLD FOR CONSTRUCTING QUANTUM BITS AND DITS FOR USE IN QUANTUM INFORMATION STORAGE AND PROCESSING

(71) Applicant: Ohio State Innovation Foundation, Columbus, OH (US)

(72) Inventors: Hannah SHAFAAT, Marina Del Rey, CA (US); Pathorn TEPTARAKULKARN, Los Angeles, CA (US)

(21) Appl. No.: 19/483,015

(22) PCT Filed: May 8, 2024
(86) PCT No.: PCT/US2024/028407

§ 371 Date: Nov. 10, 2025

Related U.S. Application Data
(60) Provisional application No. 63/464,912, filed on May 8, 2023.

(51) Int. Cl. G06N 10/40; G06N 3/00; H10K 85/00

(52) U.S. Cl. CPC G06N 10/40; G06N 3/002; H10K 85/761

(57) ABSTRACT

Disclosed are metalloproteins (e.g., vanadyl-substituted metalloproteins), such as metal-substituted rubredoxins including vanadyl-substituted rubredoxins. These metalloproteins can be used in quantum computing applications, for example, as quantum bits (qubits) or quantum dits (qudits).

### CROSS-REFERENCE TO RELATED APPLICATIONS

This application claims the benefit of, and priority to, U.S. Provisional Application No. 63/464,912, filed May 8, 2023, which is hereby incorporated by reference in its entirety.

### BACKGROUND

Classical computers operate using classical physics principles and include transistors, semiconductors, and integrated circuit technology. In order to achieve greater speed and capability, classical computers increasingly use smaller and smaller wires and logic gates on the order of microns wide. As classical computer chips reach the nanometer scale and logic gates consist of a few atoms, classical limits are approached, and quantum mechanical principles and phenomena begin to dominate. This physical limit presents a barrier to the speed with which computations may be carried out by a classical computer.

Quantum computing utilizes the principles of quantum physics, rather than classical physics, to store and manipulate data, and operates on two principles having no corollary in classical physics: superposition and entanglement. Just as a binary digit, or “bit,” is the basic unit of information in a classical computer, a quantum bit, or “qubit,” is the basic unit of information in a quantum computer. A qubit generally is a system that has two degenerate quantum states. Unlike a classical bit, which exists in one of two states (0 or 1), the qubit can exist in a superposition of both of its degenerate states. As a result, a quantum computer comprised of N qubits can undertake 2^{N} computations in a single step. Thus, as more qubits are added to a quantum computer, the computing power increases exponentially.

The superposition or “coherence” state of a qubit is difficult to maintain because interactions with the surrounding environment cause the qubit to rapidly decay into a classical or “decoherent” state, which destroys the qubit's ability to perform computations. Therefore, a primary obstacle to building a viable quantum computer is maintaining the qubit in its coherent state long enough to do useful work.

Entanglement refers to pairs of particles that have interacted at some point in the past. Entangled particles that are spatially isolated remain related. More particularly, the state of both particles of an entangled pair is always simultaneously determined. For example, measurement of a first particle of an entangled pair collapses the first particle's wave function into a single observable quantity and simultaneously determines the observable state of the second particle of the entangled pair. Pauli's exclusion principle prevents both particles of the entangled pair from occupying the same state. Thus, if one particle of the pair is determined to have a logic 1 state, the other must have a logic 0 state.

Several quantum information processing (QIP) systems for use in quantum computers are known. Each of these systems, however, has distinct disadvantages. One system uses well-established nuclear magnetic resonance (NMR) techniques to store and read information from the degenerate nuclear spin states of molecules in solution. Such a system has been used to complete basic mathematical functions, such as factoring the number 15. However, an NMR-based quantum computer requires a large number of molecules in solution to complete even relatively simple functions, and the system suffers from an attenuated signal-to-noise ratio as the number of molecules increases. Thus, the complexity of calculations that a NMR-based quantum computer is capable of carrying out may be limited.

Another QIP system uses a Co Fullerene molecule in which an atom or molecule having an unpaired electron is encased, creating an endohedral Fullerene, and encodes data in the spin states of the unpaired electrons using electron spin resonance (ESR) techniques. However, charge transfer from the enclosed atom or molecule to the Fullerene cage often rapidly occurs, which leads to quantum decoherence and loss of the information encoded in the unpaired electron. Charge transfer to the Fullerene cage also limits the make up of atoms and molecules that may be enclosed. In addition, the relatively small size of the Fullerene cavity limits the types of atoms and molecules that may be enclosed. Furthermore, inserting an atom or molecule inside the cavity of a Fullerene molecule is difficult, and the success rate for the uptake of these cargo elements is poor. These factors, coupled with the high cost of the materials needed to fabricate doped Fullerene molecules, limit the potential size and computing power of a Fullerene-based quantum computer.

An alternative QIP system utilizes an electromagnetic ion trap to store and manipulate ions. Information is encoded by manipulating the electronic state of the trapped ion's valence electrons. However, ion trap systems must operate at extremely low temperatures to maintain quantum coherence long enough to be useful, thus requiring an elaborate cooling system.

Other QIP systems make use of “quantum dots” which include small amounts of a semiconducting material enclosed within another semiconducting material. Information is encoded in the quantum dot by manipulating the energy state of particles within the enclosed semiconducting material. Existing QIP systems involve embedding several quantum dots in a solid-state microdisk. However, the excess microdisk material that surrounds the quantum dot contributes to contaminating background radiation and shortened coherence times, which degrades the performance of the system and limits the scale of a quantum dot-based quantum computer.

Semiconductor-based QIP systems typically involve a “top down” assembly approach, and employ some form of lithography and replication. Top-down approaches can be time consuming, expensive and wasteful of materials.

Thus, there exists a need for improved materials and QIP elements that avoid the shortcomings of conventional designs.

### SUMMARY

Since the start of the second quantum revolution, scientists have been developing different types of quantum materials, for the use in different aspects of quantum information technology. In the area of quantum computation and quantum information processing, the material of interest is called quantum bit (qubit), which requires 3 main properties: superposition, entanglement, and tunnelling. Different types of qubit candidates have been proposed, including molecular spin qubits. Harnessing the knowledge from chemistry, molecular spin qubit is promising in terms of controllability and tunability. However, the decoherence rate is still problematic because of either spin density or thermal motions from the ligand.

As described herein, metalloproteins can exhibit a suite of properties that render them suitable for use in quantum computing applications. By way of example, metalloproteins such as rubredoxin (Rd) can be used as a platform for binding a vanadyl ion, (V═O)²⁺. In the case of vanadyl-substituted Rd, continuous-wave electron paramagnetic resonance (cwEPR) spectroscopy showed that (V═O)Rd was stable up to at least liquid nitrogen temperature (77 K). To determine whether (V═O)Rd can be used as a qubit, pulsed-EPR techniques was used to quantify the decoherence rate which relates to the entanglement property. Once the (V═O)Rd was confirmed to be able to act as qubit, it was covalently immobilized onto a surface to be studied further as qubit material. The system can also be studied at higher temperature (liquid nitrogen temperature, 77K) than used for the study of other synthetic candidates (liquid helium temperature) which makes the system more suitable for industrial application. For use in quantum information technology, the protein-based qubits de can be immobilized onto surfaces to form an ordered and localized array, offering addressability.

Accordingly, provided herein are metal-substituted metalloproteins that comprise a non-native metal bound within a coordination environment of the metalloprotein.

The metalloprotein can comprise, for example, azurin, hemoglobin, myoglobin, hemerythrin, cytochrome, iron-sulfur protein, rubredoxin, plastocyanin, ferritin, ceruloplasmin, carbonic anhydrase, vitamin B₁₂-dependent enzyme, nitrogenase, superoxide dismutase, chlorophyll-containing protein, calmoduline, glucose-6-phosphatase, hexokinase, DNA polymerase, vanabin, arginase, catalase, hydrogenase, iron-responsive element binding protein, aconitase, urease, cytochrome oxidase, laccase, alcohol dehydrogenase, carboxy peptidase, amino peptides, β-amyloid protein, nitrate reductase, glutathione peroxidase, metallothionein, R2-like ligand binding oxidase, or a phosphatase.

In some embodiments, the metalloprotein comprises azurin. In certain embodiments, the metalloprotein comprises a naturally-occurring azurin. In other embodiments, the metalloprotein comprises a biologically active analogue, fragment, or modification of a naturally-occurring azurin.

In some embodiments, the metalloprotein comprises hemoglobin. In certain embodiments, the metalloprotein comprises a naturally-occurring hemoglobin. In other embodiments, the metalloprotein comprises a biologically active analogue, fragment, or modification of a naturally-occurring hemoglobin.

In some embodiments, the metalloprotein comprises myoglobin. In certain embodiments, the metalloprotein comprises a naturally-occurring myoglobin. In other embodiments, the metalloprotein comprises a biologically active analogue, fragment, or modification of a naturally-occurring myoglobin.

In some embodiments, the metalloprotein comprises rubredoxin. In certain embodiments, the metalloprotein comprises a naturally-occurring rubredoxin. In other embodiments, the metalloprotein comprises a biologically active analogue, fragment, or modification of a naturally-occurring rubredoxin.

In some embodiments, the metalloprotein comprises R2-like ligand binding oxidase. In certain embodiments, the metalloprotein comprises a naturally-occurring R2-like ligand binding oxidase. In other embodiments, the metalloprotein comprises a biologically active analogue, fragment, or modification of a naturally-occurring R2-like ligand binding oxidase.

In some embodiments, the non-native metal bound within the coordination environment comprises a low spin metal complex.

In some embodiments, the non-native metal is cobalt.

In some embodiments, the non-native metal is titanium.

In some embodiments, the non-native metal is manganese.

In some embodiments, the non-native metal is molybdenum (e.g., Mo(V)).

In some embodiments, the non-native metal is vanadium (e.g., V(IV)).

In some embodiments, the metal-substituted metalloprotein is stable up to at least 77 K, as indicated by continuous-wave electron paramagnetic resonance (cwEPR).

Also provided herein are metal-substituted rubredoxin polypeptides that comprise a non-native metal bound within a coordination environment of the rubredoxin polypeptide.

In some embodiments, the rubredoxin polypeptide comprises a naturally-occurring rubredoxin polypeptide. In certain embodiments, the rubredoxin polypeptide comprises an amino acid sequence of a rubredoxin from Desulfovibrio vulgaris.

In other embodiments, the rubredoxin polypeptide comprises a biologically active analogue, fragment, or modifications of a naturally occurring rubredoxin protein.

In some embodiments, the coordination environment comprises a tetradentate coordination environment.

In some embodiments, the coordination environment comprises a tetrathiolate coordination environment. In certain embodiments, the coordination environment is formed by four cysteine residues present in the rubredoxin polypeptide.

In some embodiments, the coordination environment is formed by one or more cysteine residues and one or more histidine residues present in the rubredoxin polypeptide. In certain embodiments, the coordination environment is formed by three cysteine residues and one histidine residue present in the rubredoxin polypeptide. In certain embodiments, the coordination environment is formed by two cysteine residues and two histidine residues present in the rubredoxin polypeptide. In certain embodiments, the coordination environment is formed by one cysteine residue and three histidine residues present in the rubredoxin polypeptide. In certain embodiments, the coordination environment is formed by four histidine residues present in the rubredoxin polypeptide.

In some embodiments, the coordination environment is formed by one or more cysteine residues and one or more aspartic acid residues present in the rubredoxin polypeptide. In certain embodiments, the coordination environment is formed by three cysteine residues and one aspartic acid residue present in the rubredoxin polypeptide. In certain embodiments, the coordination environment is formed by two cysteine residues and two aspartic acid residues present in the rubredoxin polypeptide. In certain embodiments, the coordination environment is formed by one cysteine residue and three aspartic acid residues present in the rubredoxin polypeptide. In certain embodiments, the coordination environment is formed by four aspartic acid residues present in the rubredoxin polypeptide.

In some embodiments, the coordination environment is formed by one or more cysteine residues and one or more glutamic acid residues present in the rubredoxin polypeptide. In certain embodiments, the coordination environment is formed by three cysteine residues and one glutamic acid residue present in the rubredoxin polypeptide. In certain embodiments, the coordination environment is formed by two cysteine residues and two glutamic acid residues present in the rubredoxin polypeptide. In certain embodiments, the coordination environment is formed by one cysteine residue and three glutamic acid residues present in the rubredoxin polypeptide. In certain embodiments, the coordination environment is formed by glutamic aspartic acid residues present in the rubredoxin polypeptide.

In some embodiments, the coordination environment is formed by one or more cysteine residues and one or more serine residues present in the rubredoxin polypeptide. In certain embodiments, the coordination environment is formed by three cysteine residues and one serine residue present in the rubredoxin polypeptide. In certain embodiments, the coordination environment is formed by two cysteine residues and two serine residues present in the rubredoxin polypeptide. In certain embodiments, the coordination environment is formed by one cysteine residue and three serine residues present in the rubredoxin polypeptide. In certain embodiments, the coordination environment is formed by four serine residues present in the rubredoxin polypeptide.

In some embodiments, the coordination environment is formed by one or more cysteine residues and one or more alanine residues present in the rubredoxin polypeptide. In certain embodiments, the coordination environment is formed by three cysteine residues and one alanine residue present in the rubredoxin polypeptide. In certain embodiments, the coordination environment is formed by two cysteine residues and two alanine residues present in the rubredoxin polypeptide. In certain embodiments, the coordination environment is formed by one cysteine residue and three alanine residues present in the rubredoxin polypeptide. In certain embodiments, the coordination environment is formed by four alanine residues present in the rubredoxin polypeptide.

In some embodiments, the coordination environment is formed by four amino acid residues present in the rubredoxin polypeptide, wherein each of the four amino acid residues is individually selected from the group consisting of a cysteine residue, a histidine residue, an aspartic acid residue, a glutamic acid residue, a serine residue, and an alanine residue. In certain embodiments, at least one of the four amino acid residues comprises a cysteine residue. In certain embodiments, at least two of the four amino acid residues comprise a cysteine residue. In certain embodiments, at least three of the four amino acid residues comprise a cysteine residue.

In some embodiments, the rubredoxin polypeptide comprises a polypeptide having at least 70%, at least 75%, at least 80%, at least 85%, at least 90%, or at least 95% homology to any one of SEQ. ID 1-SEQ. ID 105.

In some embodiments, the rubredoxin polypeptide comprises a polypeptide of any one of SEQ. ID 1-SEQ. ID 105.

In some embodiments, the non-native metal is not Ni, Co, Zn, Cd, Hg, Ga, Cu, or Mo.

In some embodiments, the non-native metal bound within the coordination environment comprises a low spin metal complex.

In some embodiments, the non-native metal is cobalt.

In some embodiments, the non-native metal is titanium.

In some embodiments, the non-native metal is manganese.

In some embodiments, the non-native metal is molybdenum (e.g., Mo(V)). In certain embodiments, the metal-substituted rubredoxin polypeptide comprises Mo(V)-rubredoxin.

In some embodiments, the non-native metal is vanadium (e.g., V(IV)). In certain embodiments, the metal-substituted rubredoxin polypeptide comprises vanadyl-rubredoxin ((V═O)-rubredoxin).

In some embodiments, the metal-substituted rubredoxin polypeptide is stable up to at least 77 K, as indicated by continuous-wave electron paramagnetic resonance (cwEPR).

The metal-substituted metalloproteins described herein and the metal-substituted rubredoxin polypeptides described herein can be immobilized on a surface. The metal-substituted metalloproteins described herein and the metal-substituted rubredoxin polypeptides described herein can be covalently attached to a triazatriangulene. The metal-substituted metalloproteins described herein and the metal-substituted rubredoxin polypeptides described herein can be covalently attached to a surface.

In certain embodiments, the surface comprises a semiconductor surface. In certain embodiments, the surface comprises graphene (e.g., graphene-MoS₂).

Also provided herein are systems comprising a periodic array of the metal-substituted metalloproteins described herein or the metal-substituted rubredoxin polypeptides described herein immobilized on a surface. In some embodiments, the metal-substituted metalloproteins described herein or the metal-substituted rubredoxin polypeptides can be covalently attached to the surface.

In certain embodiments, the surface comprises a semiconductor surface. In certain embodiments, the surface comprises graphene (e.g., graphene-MoS₂).

Also provided herein are quantum information processing platforms that comprise the metal-substituted metalloproteins described herein or the metal-substituted rubredoxin polypeptides described herein. In certain embodiments, the metal-substituted metalloproteins described herein or the metal-substituted rubredoxin polypeptides described herein can function as qubits and/or qudits within the quantum information processing platform. In certain embodiments, the quantum information processing platform can comprise a periodic array of the metal-substituted metalloproteins described herein or the metal-substituted rubredoxin polypeptides described herein immobilized on a surface. In certain embodiments, the surface comprises a semiconductor surface. In certain embodiments, the surface comprises graphene (e.g., graphene-MoS₂).

### DESCRIPTION OF DRAWINGS

FIG. 1 illustrates an example strategy for metal substitution of rubredoxin (Rd). Briefly, step 1 includes (i) reduction of FeRd with 1 M DTT solution; (ii) protein precipitation upon adding trichloroacetic acid, spin down; (iii) decant the supernatant; (iv) resuspend the solid with 0.5 M Tris buffer pH 8.0; (v) Repeat step (ii)-(iv) three times; Step 2 includes (i) Add 1.5 mM NiSO₄ solution to the apo-protein; (ii) remove excess NiSO₄ by passing through desalting column (PD10, 50 mM Tris pH 8.0 as eluent); Step 3 includes (i) reduction of NiRd with 1 M TCEP-HCl solution; (ii) protein precipitation upon adding trichloroacetic acid, spin down; (iii) decant the supernatant; (iv) resuspend the solid with 0.5 M Tris buffer pH 8.0; (v) Repeat step (ii)-(iv) five times; and Step 4 includes (i) add solution containing 8.3 mM VOSO4, 83 mM TCEP-HCl, and 417 mM Tris buffer pH8.0 to the apo-protein; (ii) let sit for 20 minutes; (iii) remove excess NiSO₄ by passing through desalting column (PD10, 10 mM PO₄ pH 8.0 as eluent).

FIGS. 2A-2C show the EPR spectra of (FIG. 2A) (V═O)Rd at 10 K with varying power (red—10 dB, orange—30 dB, and yellow—50 dB), (FIG. 2B) (V═O)Rd at 10 K (blue) and 77 K (black) and 30 dB, and (FIG. 2C) (V═O)Rd (black), 1 mM VOTCEP (blue), and 1 mM VOSO4 (light blue) at 10 K and 30 dB. All samples were prepared in 10 mM Phosphate buffer pH 8.0. 1 mM VOTCEP was prepared from dilution of a solution containing 100 μL of 100 mM VOSO4, 100 μL of 1 M TCEP-HCl, and 1.0 mL of 0.5 M Tris buffer pH 8.0 with 10 mM Phosphate buffer pH 8.0.

FIGS. 3A-3B illustrate the immobilization of [V═O]Rd on a surface. FIG. 3A shows a reaction scheme for covalent attachment of [V═O]Rd to triazatriangulene-modified surface using an amide coupling reaction. FIG. 3B illustrates an organized array of triazatriangulene on solid surface (graphene or MoS₂).

FIGS. 4A-4C show the incorporation of Mo(V), another d¹ metal, into rubredoxin (Rd) and measurement of the EPR spectra and power dependent properties up to 30 K. Briefly, Mo(VI)Rd was combined with 1 eq EuDTPA and incubated for 1 hour before passing through desalting column (PD10, 10 mM PO₄ pH 8.0 as eluent). Power and Temperature dependent X-Band EPR spectra and their saturation curve (inset) were then collected at (FIG. 4A) 10K, (FIG. 4B) 20K, and (FIG. 4C) 30K. The clear observation of EPR signal from the sample at 30 K suggests the sample could be a viable qubit. As signal should scale linearly with the square root of power, the power saturation curves shown in (FIG. 4A, inset) highlight that even at 30 K, visible saturation is observed, which is a necessary condition to prepare a superposition of states that exhibit quantum coherence with pulsed microwaves.

FIGS. 5A-5C show the EPR spectra of (FIG. 5A) (V═O)Rd at 10 K with varying power (red—10 dB, orange—30 dB, and yellow—50 dB) and corresponding saturation curve (inset), (FIG. 5B) (V═O)Rd at 10 K (blue) and 77 K (black) and 30 dB, and (FIG. 5C) (V═O)Rd (black), 1 mM VOTCEP (blue), and 1 mM VOSO4 (light blue) at 10 K and 30 dB. All samples were prepared in 10 mM Phosphate buffer pH 8.0. 1 mM VOTCEP was prepared from dilution of a solution containing 100 μL of 100 mM VOSO4, 100 μL of 1 M TCEP-HCl, and 1.0 mL of 0.5 M Tris buffer pH 8.0 with 10 mM Phosphate buffer pH 8.0. FIGS. 5A-5C show the incorporation of [V═O]²⁺ into rubredoxin. This was confirmed by the distinct EPR spectral features. The [V═O]²⁺ spin signal is observed clearly even up to 77 K, and saturates readily at 10 K, showing great promise for use as a spin qubit.

FIG. 6 shows EPR spectra of [V═O]Rd prepared using a Tris work-up. The [V═O]Rd was prepared using a process similar to that described in FIGS. 5A-5C, except that the PD10 was equilibrated with 50 mM Tris pH 8.0 (instead of 10 mM PO₄ pH 8.0). The blue trace is [VO]SO₄ in 50 mM Tris pH 8.0. The green trace is another control where Ni-substituted was used instead of apo-Rd as a control to see if the [VO]²⁺ signal observed is from [VO]Rd or just [VO]²⁺ attached to the protein surface. The black trace is [VO]Rd signal which is the same as the two controls mentioned. This suggested that Tris cannot be used to elute [VO]Rd from PD10 column. The yellow trace is the same sample as in previous slide, but was transferred into 30% Glycerol/10 mM PO₄ pH8.0. The signal almost disappeared. This suggests that the added glycerol ripped out the [VO]²⁺ metal from the protein.

FIG. 7 compares the EPR spectra of [VO]Rd to three controls at day 0 and day 4. Control #1: 1 mM [VO]SO₄+4 mM L-Cys (dissolved in 0.5 M PO₄ pH 8.0) in 1 M PO₄ pH 8.0; Control #2: 1 mM [VO]SO₄+4 mM L-Cys (dissolved in 0.5 M PO₄ pH 8.0) in 150 mM PO₄ pH 8.0; and Control #3: 1 mM [VO]SO₄+4 mM L-Cys (dissolved in 0.5 M PO₄ pH 8.0) in 150 mM Tris pH 8.0.

FIG. 8 compares the EPR spectra of [VO]Rd to two controls at day 0 and day 4. Control #4: 1 mM [VO]SO₄+4 mM L-Cys (dissolved in water) in 150 mM PO₄ pH 8.0; Control #5: 1 mM [VO]SO₄+4 mM L-Cys (dissolved in water) in 150 mM Tris pH 8.0.

FIG. 9 compares the EPR spectro of [VO]Rd to two controls at day 0 and day 4. Control #6: 1 mM [VO]SO₄+4 mM L-Cys (dissolved in 0.5 M Tris pH 8.0) in 150 mM PO₄ pH 8.0; Control #7: 1 mM [VO]SO₄+4 mM L-Cys (dissolved in 0.5 M Tris pH 8.0) in 150 mM Tris pH 8.0.

FIG. 10 is a schematic illustration showing a (top) classical bit and (bottom) qubit. (Left) Qubits can be in any superposition state along the Bloch sphere; (right) electron spin qubits are manipulated through a magnetic field and microwave pulses.

FIG. 11 illustrates example (top) protein ligand scaffolds and (bottom) vanadyl-bound active sites for example metalloproteins that can be used as qubits. Proteins are not drawn to-scale.

FIG. 12 shows an absorption and (inset) 77 K EPR spectra of vanadium-substituted azurin (VAz). The shift in optical features indicates redox activity while the EPR signals are characteristic of S=½ VII species in an asymmetric (i.e., protein based) environment.

FIG. 13 illustrates [V═O]Rd arrayed on a surface (in this example attached to ordered graphite surface). This process can take advantage of site-selective labeling and peptide-bond coupling chemistry.

FIG. 14 illustrates some of the characteristics of an example metalloprotein, rubredoxin (Rd).

FIG. 15 schematically illustrates the incorporation of [VO]²⁺ into Rd.

FIG. 16 summarizes the magnetic properties of [VO]Rd.

### DETAILED DESCRIPTION

Unless otherwise defined, all technical and scientific terms used herein have the same meaning as commonly understood by one of ordinary skill in the art to which this invention belongs. Methods and materials are described herein for use in the present invention; other, suitable methods and materials known in the art can also be used. The materials, methods, and examples are illustrative only and not intended to be limiting. All publications, patent applications, patents, sequences, database entries, and other references mentioned herein are incorporated by reference in their entirety. In case of conflict, the present specification, including definitions, will control.

Disclosed are the components to be used to prepare the disclosed compositions as well as the compositions themselves to be used within the systems methods disclosed herein. These and other materials are disclosed herein, and it is understood that when combinations, subsets, interactions, groups, etc. of these materials are disclosed that while specific reference of each various individual and collective combinations and permutation of these compounds may not be explicitly disclosed, each is specifically contemplated and described herein. For example, if a particular metalloprotein is disclosed and discussed and a number of modifications that can be made to a number of molecules including the metalloprotein are discussed, specifically contemplated is each and every combination and permutation of the metalloprotein and the modifications that are possible unless specifically indicated to the contrary. Thus, if a class of molecules A, B, and C are disclosed as well as a class of molecules D, E, and F and an example of a combination molecule, A-D is disclosed, then even if each is not individually recited each is individually and collectively contemplated meaning combinations, A-E, A-F, B-D, B-E, B-F, C-D, C-E, and C-F are considered disclosed. Likewise, any subset or combination of these is also disclosed. Thus, for example, the sub-group of A-E, B-F, and C-E would be considered disclosed. This concept applies to all aspects of this application including, but not limited to, steps in methods of making and using the disclosed compositions. Thus, if there are a variety of additional steps that can be performed it is understood that each of these additional steps can be performed with any specific embodiment or combination of embodiments of the disclosed methods.

It is understood that one way to define any known variants and derivatives or those that might arise, of the disclosed proteins (polypeptides) herein is through defining the variants and derivatives in terms of homology to specific known sequences. For example, a Table below sets forth particular amino acid sequences of example rubredoxin polypeptides. Specifically disclosed are variants of these and other proteins herein disclosed which have at least, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99 percent homology to the stated sequences. Those of skill in the art readily understand how to determine the homology of two proteins. For example, the homology can be calculated after aligning the two sequences so that the homology is at its highest level. Another way of calculating homology can be performed by published algorithms.

Optimal alignment of sequences for comparison may be conducted by the local homology algorithm of Smith and Waterman Adv. Appl. Math. 2: 482 (1981), by the homology alignment algorithm of Needleman and Wunsch, J. MoL Biol. 48: 443 (1970), by the search for similarity method of Pearson and Lipman, Proc. Natl. Acad. Sci. U.S.A. 85: 2444 (1988), by computerized implementations of these algorithms (GAP, BESTFIT, FASTA, and TFASTA in the Wisconsin Genetics Software Package, Genetics Computer Group, 575 Science Dr., Madison, WI), or by inspection.

The same types of homology can be obtained for nucleic acids by for example the algorithms disclosed in Zuker, M. Science 244:48-52, 1989, Jaeger et al. Proc. Natl. Acad. Sci. USA 86:7706-7710, 1989, Jaeger et al. Methods Enzymol. 183:281-306, 1989 which are herein incorporated by reference for at least material related to nucleic acid alignment.

As discussed herein there are numerous variants of the metalloproteins and polypeptides that are known and herein contemplated. In addition, to the known functional metalloproteins and polypeptides strain variants there are derivatives of the metalloproteins and polypeptides which also function in the disclosed methods and compositions. Protein variants and derivatives are well understood to those of skill in the art and in can involve amino acid sequence modifications. For example, amino acid sequence modifications typically fall into one or more of three classes: substitutional, insertional or deletional variants. Insertions include amino and/or carboxyl terminal fusions as well as intrasequence insertions of single or multiple amino acid residues. Insertions ordinarily will be smaller insertions than those of amino or carboxyl terminal fusions, for example, on the order of one to four residues. Immunogenic fusion protein derivatives, such as those described in the examples, are made by fusing a polypeptide sufficiently large to confer immunogenicity to the target sequence by cross-linking in vitro or by recombinant cell culture transformed with DNA encoding the fusion. Deletions are characterized by the removal of one or more amino acid residues from the protein sequence. Typically, no more than about from 2 to 6 residues are deleted at any one site within the protein molecule. These variants ordinarily are prepared by site specific mutagenesis of nucleotides in the DNA encoding the protein, thereby producing DNA encoding the variant, and thereafter expressing the DNA in recombinant cell culture. Techniques for making substitution mutations at predetermined sites in DNA having a known sequence are well known, for example M13 primer mutagenesis and PCR mutagenesis. Amino acid substitutions are typically of single residues, but can occur at a number of different locations at once; insertions usually will be on the order of about from 1 to 10 amino acid residues; and deletions will range about from 1 to 30 residues. Deletions or insertions preferably are made in adjacent pairs, i.e. a deletion of 2 residues or insertion of 2 residues. Substitutions, deletions, insertions or any combination thereof may be combined to arrive at a final construct. The mutations must not place the sequence out of reading frame and preferably will not create complementary regions that could produce secondary mRNA structure. Substitutional variants are those in which at least one residue has been removed and a different residue inserted in its place. Such substitutions generally are made in accordance with the following Tables 1 and 2 and are referred to as conservative substitutions.

TABLE 1
Amino Acid Abbreviations

| | |
|---|---|
| Amino Acid | Abbreviations |

| | | |
|---|---|---|
| Alanine | Ala | A |
| allosoleucine | AIle | |
| Arginine | Arg | R |
| asparagine | Asn | N |
| aspartic acid | Asp | D |
| Cysteine | Cys | C |
| glutamic acid | Glu | E |
| Glutamine | Gln | Q |
| Glycine | Gly | G |
| Histidine | His | H |
| Isolelucine | Ile | I |
| Leucine | Leu | L |
| Lysine | Lys | K |
| phenylalanine | Phe | F |
| proline | Pro | P |
| pyroglutamic acid | pGlu | |
| Serine | Ser | S |
| Threonine | Thr | T |
| Tyrosine | Tyr | Y |
| Tryptophan | Trp | W |
| Valine | Val | V |

TABLE 2
Amino Acid Substitutions.
Original Residue (left) and Exemplary Conservative Substitutions
(right) are shown. Others are known in the art.

| | |
|---|---|
| Ala | Ser |
| Arg | Lys; Gln |
| Asn | Gln; His |
| Asp | Glu |
| Cys | Ser |
| Gln | Asn, Lys |
| Glu | Asp |
| Gly | Pro |
| His | Asn; Gln |
| Ile | Leu; Val |
| Leu | Ile; Val |
| Lys | Arg; Gln |
| Met | Leu; Ile |
| Phe | Met; Leu; Tyr |
| Ser | Thr |
| Thr | Ser |
| Trp | Tyr |
| Tyr | Trp; Phe |
| Val | Ile; Leu |

Substantial changes in function or immunological identity are made by selecting substitutions that are less conservative than those in Table 2, i.e., selecting residues that differ more significantly in their effect on maintaining (a) the structure of the polypeptide backbone in the area of the substitution, for example as a sheet or helical conformation, (b) the charge or hydrophobicity of the molecule at the target site or (c) the bulk of the side chain. The substitutions which in general are expected to produce the greatest changes in the protein properties will be those in which (a) a hydrophilic residue, e.g. seryl or threonyl, is substituted for (or by) a hydrophobic residue, e.g. leucyl, isoleucyl, phenylalanyl, valyl or alanyl; (b) a cysteine or proline is substituted for (or by) any other residue; (c) a residue having an electropositive side chain, e.g., lysyl, arginyl, or histidyl, is substituted for (or by) an electronegative residue, e.g., glutamyl or aspartyl; or (d) a residue having a bulky side chain, e.g., phenylalanine, is substituted for (or by) one not having a side chain, e.g., glycine, in this case, (e) by increasing the number of sites for sulfation and/or glycosylation.

For example, the replacement of one amino acid residue with another that is biologically and/or chemically similar is known to those skilled in the art as a conservative substitution. For example, a conservative substitution would be replacing one hydrophobic residue for another, or one polar residue for another. The substitutions include combinations such as, for example, Gly, Ala; Val, Ile, Leu; Asp, Glu; Asn, Gln; Ser, Thr; Lys, Arg; and Phe, Tyr. Such conservatively substituted variations of each explicitly disclosed sequence are included within the mosaic polypeptides provided herein.

Substitutional or deletional mutagenesis can be employed to insert sites for N-glycosylation (Asn-X-Thr/Ser) or O-glycosylation (Ser or Thr). Deletions of cysteine or other labile residues also may be desirable. Deletions or substitutions of potential proteolysis sites, e.g. Arg, is accomplished for example by deleting one of the basic residues or substituting one by glutaminyl or histidyl residues.

Certain post-translational derivatizations are the result of the action of recombinant host cells on the expressed polypeptide. Glutaminyl and asparaginyl residues are frequently post-translationally deamidated to the corresponding glutamyl and asparyl residues. Alternatively, these residues are deamidated under mildly acidic conditions. Other post-translational modifications include hydroxylation of proline and lysine, phosphorylation of hydroxyl groups of seryl or threonyl residues, methylation of the o-amino groups of lysine, arginine, and histidine side chains (T. E. Creighton, Proteins: Structure and Molecular Properties, W. H. Freeman & Co., San Francisco pp 79-86 [1983]), acetylation of the N-terminal amine and, in some instances, amidation of the C-terminal carboxyl.

As discussed above, it is understood that one way to define the variants and derivatives of the disclosed proteins herein is through defining the variants and derivatives in terms of homology/identity to specific known sequences. For example, SEQ. ID NO. 1-SEQ. ID NO. 105 sets forth example amino acids sequences of rubredoxin polypeptides. Specifically disclosed are variants of these and other proteins herein disclosed which have at least, 70% or 75% or 80% or 85% or 90% or 95% homology to the stated sequence. Those of skill in the art readily understand how to determine the homology of two proteins. For example, the homology can be calculated after aligning the two sequences so that the homology is at its highest level.

Another way of calculating homology can be performed by published algorithms. Optimal alignment of sequences for comparison may be conducted by the local homology algorithm of Smith and Waterman Adv. Appl. Math. 2: 482 (1981), by the homology alignment algorithm of Needleman and Wunsch, J. MoL Biol. 48: 443 (1970), by the search for similarity method of Pearson and Lipman, Proc. Natl. Acad. Sci. U.S.A. 85: 2444 (1988), by computerized implementations of these algorithms (GAP, BESTFIT, FASTA, and TFASTA in the Wisconsin Genetics Software Package, Genetics Computer Group, 575 Science Dr., Madison, WI), or by inspection.

The same types of homology can be obtained for nucleic acids by for example the algorithms disclosed in Zuker, M. Science 244:48-52, 1989, Jaeger et al. Proc. Natl. Acad. Sci. USA 86:7706-7710, 1989, Jaeger et al. Methods Enzymol. 183:281-306, 1989.

It is understood that the description of conservative mutations and homology can be combined together in any combination, such as embodiments that have at least 70% homology to a particular sequence wherein the variants are conservative mutations.

As this specification discusses various proteins and protein sequences it is understood that the nucleic acids that can encode those protein sequences are also disclosed. This would include all degenerate sequences related to a specific protein sequence, i.e. all nucleic acids having a sequence that encodes one particular protein sequence as well as all nucleic acids, including degenerate nucleic acids, encoding the disclosed variants and derivatives of the protein sequences. Thus, while each particular nucleic acid sequence may not be written out herein, it is understood that each and every sequence is in fact disclosed and described herein through the disclosed protein sequence. It is also understood that while no amino acid sequence indicates what particular DNA sequence encodes that protein within an organism, where particular variants of a disclosed protein are disclosed herein, the known nucleic acid sequence that encodes that protein in the particular organism from which that protein arises is also known and herein disclosed and described.

It is understood that there are numerous amino acid and peptide analogs which can be incorporated into the disclosed compositions. For example, there are numerous D amino acids or amino acids which have a different functional substituent then the amino acids shown in Table 1 and Table 2. The opposite stereo isomers of naturally occurring peptides are disclosed, as well as the stereo isomers of peptide analogs. These amino acids can readily be incorporated into polypeptide chains by charging tRNA molecules with the amino acid of choice and engineering genetic constructs that utilize, for example, amber codons, to insert the analog amino acid into a peptide chain in a site specific way.

Molecules can be produced that resemble peptides, but which are not connected via a natural peptide linkage. For example, linkages for amino acids or amino acid analogs can include CH₂NH—, —CH₂S—, —CH₂—CH₂—, —CH═CH— (cis and trans), —COCH₂—, —CH(OH)CH₂—, and —CHH₂SO (These and others can be found in Spatola, A. F. in Chemistry and Biochemistry of Amino Acids, Peptides, and Proteins, B. Weinstein, eds., Marcel Dekker, New York, p. 267 (1983); Spatola, A. F., Vega Data (March 1983), Vol. 1, Issue 3, Peptide Backbone Modifications (general review); Morley, Trends Pharm Sci (1980) pp. 463-468; Hudson, D. et al., Int J Pept Prot Res 14:177-185 (1979) (—CH₂NH—, CH₂CH₂—); Spatola et al. Life Sci 38:1243-1249 (1986) (—CH H₂—S); Hann J. Chem. Soc Perkin Trans. I 307-314 (1982) (—CH—CH—, cis and trans); Almquist et al. J. Med. Chem. 23:1392-1398 (1980) (—COCH₂—); Jennings-White et al. Tetrahedron Lett 23:2533 (1982) (—COCH₂—); Szelke et al. European Appln, EP 45665 CA (1982): 97:39405 (1982) (—CH(OH)CH₂—); Holladay et al. Tetrahedron. Lett 24:4401-4404 (1983) (—C(OH)CH₂—); and Hruby Life Sci 31:189-199 (1982) (—CH₂—S—); each of which is incorporated herein by reference. A particularly preferred non-peptide linkage is —CH₂NH—. It is understood that peptide analogs can have more than one atom between the bond atoms, such as b-alanine, g-aminobutyric acid, and the like.

Amino acid analogs and analogs and peptide analogs often have enhanced or desirable properties, such as, more economical production, greater chemical stability, enhanced pharmacological properties (half-life, absorption, potency, efficacy, etc.), altered specificity (e.g., a broad-spectrum of biological activities), reduced antigenicity, and others.

D-amino acids can be used to generate more stable peptides, because D amino acids are not recognized by peptidases and such. Systematic substitution of one or more amino acids of a consensus sequence with a D-amino acid of the same type (e.g., D-lysine in place of L-lysine) can be used to generate more stable peptides. Cysteine residues can be used to cyclize or attach two or more peptides together. This can be beneficial to constrain peptides into particular conformations.

When used herein to describe a metalloprotein and protein (polypeptide) analogue, fragment, or modification thereof, the term “biologically active” means that the metalloprotein and protein (polypeptide) analogue, fragment or modification thereof possesses a coordination site (either a natural coordination site or a modified coordination site) that can bind the native metal present in the metalloprotein or protein (polypeptide). Biological activity (e.g., iron-binding activity) of a metalloprotein or protein (polypeptide) can be easily assayed by simply observing the characteristic visible spectrum of the metalloprotein or protein (polypeptide) that includes a bound metal. Moreover, binding can be visually detected in many instances via a color change.

An “analogue” of a metalloprotein or a protein (polypeptide) means a metalloprotein or protein (polypeptide) that contains one or more amino acid substitutions, deletions, additions, or rearrangements. For example, it is well-known in the art of protein biochemistry that an amino acid belonging to a grouping of amino acids having a particular size or characteristic (such as charge, hydrophobicity and hydrophilicity) can often be substituted for another amino acid without altering the activity of a protein, particularly in regions of the protein that are not directly associated with biological activity. Thus, in some embodiments, the metalloprotein and protein (polypeptide) can be a metalloprotein and protein (polypeptide) that contains amino acid substitutions at sites such that the metal-binding activity of the metalloprotein or protein (polypeptide) is not eliminated (e.g., such that the coordination site is conserved). Substitutes for an amino acid may be selected from other members of the class to which the amino acid belongs. For example, nonpolar (hydrophobic) amino acids include alanine, leucine, isoleucine, valine, proline, phenylalanine, tryptophan, and tyrosine. Polar neutral amino acids include glycine, serine, threonine, cysteine, tyrosine, asparagine and glutamine. The positively charged (basic) amino acids include arginine, lysine and histidine. The negatively charged (acidic) amino acids include aspartic acid and glutamic acid. Examples of preferred conservative substitutions include Lys for Arg and vice versa to maintain a positive charge; Glu for Asp and vice versa to maintain a negative charge; Ser for Thr so that a free —OH is maintained; and Gin for Asn to maintain a free NH₂.

Likewise, metalloproteins and proteins (polypeptide) containing deletions or additions of one or more contiguous or noncontiguous amino acids that do not eliminate the biological activity of the metalloprotein or protein (polypeptide) are also contemplated. Preferably, a metalloprotein or protein (polypeptide) analogue has at least about 80% amino acid identity with a reference metalloprotein or protein (polypeptide); more preferably it has at least about 90% amino acid identity with a reference metalloprotein or protein (polypeptide).

“Modified” metalloproteins and proteins (polypeptides) includes metalloproteins and proteins (polypeptides) chemically or enzymatically derivatized at one or more constituent amino acid, including side chain modifications, backbone modifications, and N- and C-terminal modifications including acetylation, hydroxylation, methylation, amidation, and the attachment of carbohydrate or lipid moieties, cofactors, and the like.

Provided herein are metal-substituted metalloproteins that comprise a non-native metal bound within a coordination environment of the metalloprotein.

The metalloprotein can comprise, for example, azurin, hemoglobin, myoglobin, hemerythrin, cytochrome, iron-sulfur protein, rubredoxin, plastocyanin, ferritin, ceruloplasmin, carbonic anhydrase, vitamin B₁₂-dependent enzyme, nitrogenase, superoxide dismutase, chlorophyll-containing protein, calmoduline, glucose-6-phosphatase, hexokinase, DNA polymerase, vanabin, arginase, catalase, hydrogenase, iron-responsive element binding protein, aconitase, urease, cytochrome oxidase, laccase, alcohol dehydrogenase, carboxy peptidase, amino peptides, β-amyloid protein, nitrate reductase, glutathione peroxidase, metallothionein, R2-like ligand binding oxidase, or a phosphatase.

In some embodiments, the metalloprotein comprises a naturally-occurring metalloprotein, such as, for example, naturally-occurring azurin, hemoglobin, myoglobin, hemerythrin, cytochrome, iron-sulfur protein, rubredoxin, plastocyanin, ferritin, ceruloplasmin, carbonic anhydrase, vitamin B₁₂-dependent enzyme, nitrogenase, superoxide dismutase, chlorophyll-containing protein, calmoduline, glucose-6-phosphatase, hexokinase, DNA polymerase, vanabin, arginase, catalase, hydrogenase, iron-responsive element binding protein, aconitase, urease, cytochrome oxidase, laccase, alcohol dehydrogenase, carboxy peptidase, amino peptides, β-amyloid protein, nitrate reductase, glutathione peroxidase, metallothionein, R2-like ligand binding oxidase, or phosphatase.

In other embodiments, the metalloprotein comprises a biologically active analogue, fragment, or modification of a naturally-occurring metalloprotein, such as, for example, biologically active analogue, fragment, or modification of naturally-occurring azurin, hemoglobin, myoglobin, hemerythrin, cytochrome, iron-sulfur protein, rubredoxin, plastocyanin, ferritin, ceruloplasmin, carbonic anhydrase, vitamin B₁₂-dependent enzyme, nitrogenase, superoxide dismutase, chlorophyll-containing protein, calmoduline, glucose-6-phosphatase, hexokinase, DNA polymerase, vanabin, arginase, catalase, hydrogenase, iron-responsive element binding protein, aconitase, urease, cytochrome oxidase, laccase, alcohol dehydrogenase, carboxy peptidase, amino peptides, β-amyloid protein, nitrate reductase, glutathione peroxidase, metallothionein, R2-like ligand binding oxidase, or phosphatase.

In some embodiments, the metalloprotein comprises azurin. In certain embodiments, the metalloprotein comprises a naturally-occurring azurin. In other embodiments, the metalloprotein comprises a biologically active analogue, fragment, or modification of a naturally-occurring azurin.

In some embodiments, the metalloprotein comprises hemoglobin. In certain embodiments, the metalloprotein comprises a naturally-occurring hemoglobin. In other embodiments, the metalloprotein comprises a biologically active analogue, fragment, or modification of a naturally-occurring hemoglobin.

In some embodiments, the metalloprotein comprises myoglobin. In certain embodiments, the metalloprotein comprises a naturally-occurring myoglobin. In other embodiments, the metalloprotein comprises a biologically active analogue, fragment, or modification of a naturally-occurring myoglobin.

In some embodiments, the metalloprotein comprises rubredoxin. In certain embodiments, the metalloprotein comprises a naturally-occurring rubredoxin. In other embodiments, the metalloprotein comprises a biologically active analogue, fragment, or modification of a naturally-occurring rubredoxin.

In some embodiments, the metalloprotein comprises R2-like ligand binding oxidase. In certain embodiments, the metalloprotein comprises a naturally-occurring R2-like ligand binding oxidase. In other embodiments, the metalloprotein comprises a biologically active analogue, fragment, or modification of a naturally-occurring R2-like ligand binding oxidase.

In some embodiments, the non-native metal bound within the coordination environment comprises a low spin metal complex.

In some embodiments, the non-native metal is cobalt.

In some embodiments, the non-native metal is titanium.

In some embodiments, the non-native metal is manganese.

In some embodiments, the non-native metal is molybdenum (e.g., Mo(V)).

In some embodiments, the non-native metal is vanadium (e.g., V(IV)).

In some embodiments, the metal-substituted metalloprotein is stable up to at least 77 K, as indicated by continuous-wave electron paramagnetic resonance (cwEPR).

Also provided herein are metal-substituted rubredoxin polypeptides that comprise a non-native metal bound within a coordination environment of the rubredoxin polypeptide.

Rubredoxin is an electron carrier protein originally isolated and then cloned from the anaerobic sulfate reducing bacteria, Desulfovibrio vulgaris. Since then, rubredoxins from several different anaerobic organisms have been discovered and characterized. Rubredoxin is a small redox protein (5.6 kD) carrying a single non-haem iron center. The crystal structure of the protein has been solved and reveals a free carboxy-terminal end, making it well-suited for fusing peptides. The iron center imparts a red color to the protein (absorption maxima at 390 nm and 495 nm) providing a visible marker for easy monitoring during purification protocols. The red color also serves indicator as to whether the fusion protein has folded correctly, since an incorrectly folded protein will not bind the metal. Recombinant rubredoxin can be produced at high levels (50-60 mg/L of purified protein) in E. coli and is very soluble, biologically active and stable. Conveniently, rubredoxin is a thermostable protein and can withstand 70° C.-80° C. for more than an hour without denaturation. It also retains its metal center in denaturing agents like 0.5% SDS and 6M urea.

The rubredoxin can comprise any suitable rubredoxin polypeptide. In some embodiments, the rubredoxin polypeptide has the wild-type amino acid sequence of a rubredoxin protein obtained from an anaerobic bacterium, preferably from Desulfovibrio, Clostridium, Desulfoarculus or Pyrococcus spp., more preferably from D. vulgaris, D. vulgaris (Hildenborough), C. pasteurianum, C. butyricum, D. baarsii or P. furiosa. GenBank Accession numbers for nucleotide sequences encoding rubredoxins include D76419 (rub gene for D. vulgaris), M28848 (rub gene for D. vulgaris (Hildenborough), M60116 (C. pasteurianum rubredoxin gene), YI 1875 (C. butyricum rubredoxin gene), and X99543 for D. baarsii. A particularly preferred amino acid sequence for the rubredoxin polypeptide is an amino acid sequence of a rubredoxin from D. vulgaris. In these embodiments, the amino acid sequence of the rubredoxin polypeptide is not intended to be limited to the exact wild-type amino acid sequence of naturally occurring rubredoxin proteins; rather, the rubredoxin polypeptide can also include biologically active analogues, fragments, or modifications of any and all naturally occurring rubredoxin proteins.

When used herein to describe a rubredoxin analogue, fragment, or modification thereof, the term “biologically active” means that the rubredoxin analogue, fragment or modification thereof possesses a tetrathiolate coordination site that can bind a metal such as iron, or a modified coordination site that can bind a metal such as iron (e.g., a tetradentate coordination site or in which one or more of the thiolates (cysteine residues) has been replaced with an alternative ligand (e.g., a cysteine residue has been replace with a histidine or serine residue) or a non-coordinating amino acid. Biological activity (e.g., iron-binding activity) of a rubredoxin polypeptide can be easily assayed by simply observing the characteristic visible spectrum of a rubredoxin that has bound iron. Moreover, iron binding can be visually detected because the bound complex is red.

Naturally occurring rubredoxin is a small protein; for example, rubredoxin from D. vulgaris contains about 52 amino acids. A “fragment” of rubredoxin means a rubredoxin that has been truncated at the C-terminus; preferably, the fragment is at least about 40 amino acids in length, more preferably it is at least about 45 amino acids in length.

An “analogue” of rubredoxin means a rubredoxin that contains one or more amino acid substitutions, deletions, additions, or rearrangements. For example, it is well-known in the art of protein biochemistry that an amino acid belonging to a grouping of amino acids having a particular size or characteristic (such as charge, hydrophobicity and hydrophilicity) can often be substituted for another amino acid without altering the activity of a protein, particularly in regions of the protein that are not directly associated with biological activity. Thus, in some embodiments, the rubredoxin polypeptide can be a rubredoxin that contains amino acid substitutions at sites such that the iron-binding activity of the polypeptide is not eliminated (i.e., the tetrathiolate coordination site is conserved). Substitutes for an amino acid may be selected from other members of the class to which the amino acid belongs. For example, nonpolar (hydrophobic) amino acids include alanine, leucine, isoleucine, valine, proline, phenylalanine, tryptophan, and tyrosine. Polar neutral amino acids include glycine, serine, threonine, cysteine, tyrosine, asparagine and glutamine. The positively charged (basic) amino acids include arginine, lysine and histidine. The negatively charged (acidic) amino acids include aspartic acid and glutamic acid. Examples of preferred conservative substitutions include Lys for Arg and vice versa to maintain a positive charge; Glu for Asp and vice versa to maintain a negative charge; Ser for Thr so that a free —OH is maintained; and Gin for Asn to maintain a free NH₂.

Likewise, rubredoxin polypeptides containing deletions or additions of one or more contiguous or noncontiguous amino acids that do not eliminate the biological activity of rubredoxin are also contemplated. Preferably, a rubredoxin analogue has at least about 80% amino acid identity with a reference rubredoxin protein; more preferably it has at least about 90% amino acid identity with a reference rubredoxin protein. The reference rubredoxin protein is preferably a rubredoxin from D. vulgaris.

Amino acid identity is defined in the context of a homology comparison between the rubredoxin analogue and the reference rubredoxin protein. The two amino acid sequences are aligned in a way that maximizes the number of amino acids that they have in common along the lengths of their sequences; gaps in either or both sequences are permitted in making the alignment in order to maximize the number of shared amino acids, although the amino acids in each sequence must nonetheless remain in their proper order. The percentage amino acid identity is the higher of the following two numbers: (a) the number of amino acids that the two polypeptides have in common within the alignment, divided by the number of amino acids in the rubredoxin analogue, multiplied by 100; or (b) the number of amino acids that the two polypeptides have in common within the alignment, divided by the number of amino acids in the reference rubredoxin protein.

“Modified” rubredoxin includes rubredoxins chemically or enzymatically derivatized at one or more constituent amino acid, including side chain modifications, backbone modifications, and N- and C-terminal modifications including acetylation, hydroxylation, methylation, amidation, and the attachment of carbohydrate or lipid moieties, cofactors, and the like.

In some embodiments, the rubredoxin polypeptide comprises a naturally-occurring rubredoxin polypeptide. In certain embodiments, the rubredoxin polypeptide comprises an amino acid sequence of a rubredoxin from Desulfovibrio vulgaris.

In other embodiments, the rubredoxin polypeptide comprises a biologically active analogue, fragment, or modifications of a naturally occurring rubredoxin protein.

In some embodiments, the coordination environment comprises a tetradentate coordination environment.

In some embodiments, the coordination environment comprises a tetrathiolate coordination environment. In certain embodiments, the coordination environment is formed by four cysteine residues present in the rubredoxin polypeptide.

In some embodiments, the coordination environment is formed by one or more cysteine residues and one or more histidine residues present in the rubredoxin polypeptide. In certain embodiments, the coordination environment is formed by three cysteine residues and one histidine residue present in the rubredoxin polypeptide. In certain embodiments, the coordination environment is formed by two cysteine residues and two histidine residues present in the rubredoxin polypeptide. In certain embodiments, the coordination environment is formed by one cysteine residue and three histidine residues present in the rubredoxin polypeptide. In certain embodiments, the coordination environment is formed by four histidine residues present in the rubredoxin polypeptide.

In some embodiments, the coordination environment is formed by one or more cysteine residues and one or more aspartic acid residues present in the rubredoxin polypeptide. In certain embodiments, the coordination environment is formed by three cysteine residues and one aspartic acid residue present in the rubredoxin polypeptide. In certain embodiments, the coordination environment is formed by two cysteine residues and two aspartic acid residues present in the rubredoxin polypeptide. In certain embodiments, the coordination environment is formed by one cysteine residue and three aspartic acid residues present in the rubredoxin polypeptide. In certain embodiments, the coordination environment is formed by four aspartic acid residues present in the rubredoxin polypeptide.

In some embodiments, the coordination environment is formed by one or more cysteine residues and one or more glutamic acid residues present in the rubredoxin polypeptide. In certain embodiments, the coordination environment is formed by three cysteine residues and one glutamic acid residue present in the rubredoxin polypeptide. In certain embodiments, the coordination environment is formed by two cysteine residues and two glutamic acid residues present in the rubredoxin polypeptide. In certain embodiments, the coordination environment is formed by one cysteine residue and three glutamic acid residues present in the rubredoxin polypeptide. In certain embodiments, the coordination environment is formed by glutamic aspartic acid residues present in the rubredoxin polypeptide.

In some embodiments, the coordination environment is formed by one or more cysteine residues and one or more serine residues present in the rubredoxin polypeptide. In certain embodiments, the coordination environment is formed by three cysteine residues and one serine residue present in the rubredoxin polypeptide. In certain embodiments, the coordination environment is formed by two cysteine residues and two serine residues present in the rubredoxin polypeptide. In certain embodiments, the coordination environment is formed by one cysteine residue and three serine residues present in the rubredoxin polypeptide. In certain embodiments, the coordination environment is formed by four serine residues present in the rubredoxin polypeptide.

In some embodiments, the coordination environment is formed by one or more cysteine residues and one or more alanine residues present in the rubredoxin polypeptide. In certain embodiments, the coordination environment is formed by three cysteine residues and one alanine residue present in the rubredoxin polypeptide. In certain embodiments, the coordination environment is formed by two cysteine residues and two alanine residues present in the rubredoxin polypeptide. In certain embodiments, the coordination environment is formed by one cysteine residue and three alanine residues present in the rubredoxin polypeptide. In certain embodiments, the coordination environment is formed by four alanine residues present in the rubredoxin polypeptide.

In some embodiments, the coordination environment is formed by four amino acid residues present in the rubredoxin polypeptide, wherein each of the four amino acid residues is individually selected from the group consisting of a cysteine residue, a histidine residue, an aspartic acid residue, a glutamic acid residue, a serine residue, and an alanine residue. In certain embodiments, at least one of the four amino acid residues comprises a cysteine residue. In certain embodiments, at least two of the four amino acid residues comprise a cysteine residue. In certain embodiments, at least three of the four amino acid residues comprise a cysteine residue.

In some embodiments, the rubredoxin polypeptide comprises a polypeptide having at least 7000, at least 7500, at least 80%, at least 85%, at least 90%, or at least 95% homology to any one of SEQ. TD 1-SEQ. ID 5 in the Table below. In some embodiments, the rubredoxin polypeptide comprises a polypeptide ofany one of SEQ. ID 1-SEQ. ID 5 in the Table below.

In som embodiments, the rubredoxin polypeptide comprises an analogue of any one of SEQ. ID 1-SEQ. TD 5 in the Table below in which one or more of the coordinating cysteine residues (shown in bold and underlines) is substituted (individually or in parallel) with H, D, E, 5, or A.

Example rubredoxin polypeptides include the polypeptides listed in the Table below.

| | Amino Acid Sequence |
|---|---|
| Sequence | (Coordinating Residues are Bolded and Underlined) |
| SEQ. ID 1 | M---QKYVCNVCGYEYDPAEH------- |
| | DNVPFDQLPDDWCCPVCGVSKDQFSPA-- |
| SEQ. ID 2 | M--- |
| | QKYVCDICGYVYDPEVGDPDGGINPGTAFEDIPEDWVCPLCGVGKED |
| | FSPE-D |
| SEQ. ID 3 | M--- |
| | KRYECIVCGWIYDEELGCPEEGIAPGTKWDDIPDDWTCPECGVGKLD |
| | FEMMEV |
| SEQ. ID 4 | MIEMARYQC- |
| | MCGWVYDEDKGEPSQNIPPGTKFEDLPDTFRCPQCGLGKNAFRKID- |
| SEQ. ID 5 | M--- |
| | AKWVCKICGYIYDEDAGDPDNGISPGTKFEELPDDWVCPICGAPKSEF |
| | EKLED |
| SEQ. ID 6 | M---QKYVHNVCGYEYDPAEH------- |
| | DNVPFDQLPDDWCCPVCGVSKDQFSPA-- |
| SEQ. ID 7 | M--- |
| | QKYVHDICGYVYDPEVGDPDGGINPGTAFEDIPEDWVCPLCGVGKED |
| | FSPE-D |
| SEQ. ID 8 | M--- |
| | KRYEHIVCGWIYDEELGCPEEGIAPGTKWDDIPDDWTCPECGVGKLD |
| | FEMMEV |
| SEQ. ID 9 | MIEMARYQH- |
| | MCGWVYDEDKGEPSQNIPPGTKFEDLPDTFRCPQCGLGKNAFRKID- |
| SEQ. ID 10 | M--- |
| | AKWVHKICGYIYDEDAGDPDNGISPGTKFEELPDDWVCPICGAPKSEF |
| | EKLED |
| SEQ. ID 11 | M---QKYVCNVHGYEYDPAEH------- |
| | DNVPFDQLPDDWCCPVCGVSKDQFSPA-- |
| SEQ. ID 12 | M--- |
| | QKYVCDIHGYVYDPEVGDPDGGINPGTAFEDIPEDWVCPLCGVGKED |
| | FSPE-D |
| SEQ. ID 13 | M--- |
| | KRYECIVHGWIYDEELGCPEEGIAPGTKWDDIPDDWTCPECGVGKLD |
| | FEMMEV |
| SEQ. ID 14 | MIEMARYQC- |
| | MHGWVYDEDKGEPSQNIPPGTKFEDLPDTFRCPQCGLGKNAFRKID- |
| SEQ. ID 15 | M--- |
| | AKWVCKIHGYIYDEDAGDPDNGISPGTKFEELPDDWVCPICGAPKSEF |
| | EKLED |
| SEQ. ID 16 | M---QKYVCNVCGYEYDPAEH------- |
| | DNVPFDQLPDDWCHPVCGVSKDQFSPA-- |
| SEQ. ID 17 | M--- |
| | QKYVCDICGYVYDPEVGDPDGGINPGTAFEDIPEDWVHPLCGVGKED |
| | FSPE-D |
| SEQ. ID 18 | M--- |
| | KRYECIVCGWIYDEELGCPEEGIAPGTKWDDIPDDWTHPECGVGKLD |
| | FEMMEV |
| SEQ. ID 19 | MIEMARYQC- |
| | MCGWVYDEDKGEPSQNIPPGTKFEDLPDTFRHPQCGLGKNAFRKID- |
| SEQ. ID 20 | M--- |
| | AKWVCKICGYIYDEDAGDPDNGISPGTKFEELPDDWVHPICGAPKSEF |
| | EKLED |
| SEQ. ID 21 | M---QKYVCNVCGYEYDPAEH------- |
| | DNVPFDQLPDDWCCPVHGVSKDQFSPA-- |
| SEQ. ID 22 | M--- |
| | QKYVCDICGYVYDPEVGDPDGGINPGTAFEDIPEDWVCPLHGVGKED |
| | FSPE-D |
| SEQ. ID 23 | M--- |
| | KRYECIVCGWIYDEELGCPEEGIAPGTKWDDIPDDWTCPEHGVGKLD |
| | FEMMEV |
| SEQ. ID 24 | MIEMARYQC- |
| | MCGWVYDEDKGEPSQNIPPGTKFEDLPDTFRCPQHGLGKNAFRKID- |
| SEQ. ID 25 | M--- |
| | AKWVCKICGYIYDEDAGDPDNGISPGTKFEELPDDWVCPIHGAPKSEF |
| | EKLED |
| SEQ. ID 26 | M---QKYVDNVCGYEYDPAEH------- |
| | DNVPFDQLPDDWCCPVCGVSKDQFSPA-- |
| SEQ. ID 27 | M--- |
| | QKYVDDICGYVYDPEVGDPDGGINPGTAFEDIPEDWVCPLCGVGKED |
| | FSPE-D |
| SEQ. ID 28 | M--- |
| | KRYEDIVCGWIYDEELGCPEEGIAPGTKWDDIPDDWTCPECGVGKLD |
| | FEMMEV |
| SEQ. ID 29 | MIEMARYQD- |
| | MCGWVYDEDKGEPSQNIPPGTKFEDLPDTFRCPQCGLGKNAFRKID- |
| SEQ. ID 30 | M--- |
| | AKWVDKICGYIYDEDAGDPDNGISPGTKFEELPDDWVCPICGAPKSEF |
| | EKLED |
| SEQ. ID 31 | M---QKYVCNVDGYEYDPAEH------- |
| | DNVPFDQLPDDWCCPVCGVSKDQFSPA-- |
| SEQ. ID 32 | M--- |
| | QKYVCDIDGYVYDPEVGDPDGGINPGTAFEDIPEDWVCPLCGVGKED |
| | FSPE-D |
| SEQ. ID 33 | M--- |
| | KRYECIVDGWIYDEELGCPEEGIAPGTKWDDIPDDWTCPECGVGKLD |
| | FEMMEV |
| SEQ. ID 34 | MIEMARYQC- |
| | MDGWVYDEDKGEPSQNIPPGTKFEDLPDTFRCPQCGLGKNAFRKID- |
| SEQ. ID 35 | M--- |
| | AKWVCKIDGYIYDEDAGDPDNGISPGTKFEELPDDWVCPICGAPKSEF |
| | EKLED |
| SEQ. ID 36 | M---QKYVCNVCGYEYDPAEH------- |
| | DNVPFDQLPDDWCDPVCGVSKDQFSPA-- |
| SEQ. ID 37 | M--- |
| | QKYVCDICGYVYDPEVGDPDGGINPGTAFEDIPEDWVDPLCGVGKED |
| | FSPE-D |
| SEQ. ID 38 | M--- |
| | KRYECIVCGWIYDEELGCPEEGIAPGTKWDDIPDDWTDPECGVGKLD |
| | FEMMEV |
| SEQ. ID 39 | MIEMARYQC- |
| | MCGWVYDEDKGEPSQNIPPGTKFEDLPDTFRDPQCGLGKNAFRKID- |
| SEQ. ID 40 | M--- |
| | AKWVCKICGYIYDEDAGDPDNGISPGTKFEELPDDWVDPICGAPKSEF |
| | EKLED |
| SEQ. ID 41 | M---QKYVCNVCGYEYDPAEH------- |
| | DNVPFDQLPDDWCCPVDGVSKDQFSPA-- |
| SEQ. ID 42 | M--- |
| | QKYVCDICGYVYDPEVGDPDGGINPGTAFEDIPEDWVCPLDGVGKED |
| | FSPE-D |
| SEQ. ID 43 | M--- |
| | KRYECIVCGWIYDEELGCPEEGIAPGTKWDDIPDDWTCPEDGVGKLD |
| | FEMMEV |
| SEQ. ID 44 | MIEMARYQC- |
| | MCGWVYDEDKGEPSQNIPPGTKFEDLPDTFRCPQDGLGKNAFRKID- |
| SEQ. ID 45 | M--- |
| | AKWVCKICGYIYDEDAGDPDNGISPGTKFEELPDDWVCPIDGAPKSEF |
| | EKLED |
| SEQ. ID 46 | M---QKYVeNVCGYEYDPAEH------- |
| | DNVPFDQLPDDWCCPVCGVSKDQFSPA-- |
| SEQ. ID 47 | M--- |
| | QKYVEDICGYVYDPEVGDPDGGINPGTAFEDIPEDWVCPLCGVGKED |
| | FSPE-D |
| SEQ. ID 48 | M--- |
| | KRYEEIVCGWIYDEELGCPEEGIAPGTKWDDIPDDWTCPECGVGKLD |
| | FEMMEV |
| SEQ. ID 49 | MIEMARYQE- |
| | MCGWVYDEDKGEPSQNIPPGTKFEDLPDTFRCPQCGLGKNAFRKID- |
| SEQ. ID 50 | M--- |
| | AKWVEKICGYIYDEDAGDPDNGISPGTKFEELPDDWVCPICGAPKSEF |
| | EKLED |
| SEQ. ID 51 | M---QKYVCNVEGYEYDPAEH------- |
| | DNVPFDQLPDDWCCPVCGVSKDQFSPA-- |
| SEQ. ID 52 | M--- |
| | QKYVCDIEGYVYDPEVGDPDGGINPGTAFEDIPEDWVCPLCGVGKED |
| | FSPE-D |
| SEQ. ID 53 | M--- |
| | KRYECIVEGWIYDEELGCPEEGIAPGTKWDDIPDDWTCPECGVGKLD |
| | FEMMEV |
| SEQ. ID 54 | MIEMARYQC- |
| | MEGWVYDEDKGEPSQNIPPGTKFEDLPDTFRCPQCGLGKNAFRKID- |
| SEQ. ID 55 | M--- |
| | AKWVCKIEGYIYDEDAGDPDNGISPGTKFEELPDDWVCPICGAPKSEF |
| | EKLED |
| SEQ. ID 56 | M---QKYVCNVCGYEYDPAEH------- |
| | DNVPFDQLPDDWCEPVCGVSKDQFSPA-- |
| SEQ. ID 57 | M--- |
| | QKYVCDICGYVYDPEVGDPDGGINPGTAFEDIPEDWVEPLCGVGKED |
| | FSPE-D |
| SEQ. ID 58 | M--- |
| | KRYECIVCGWIYDEELGCPEEGIAPGTKWDDIPDDWTEPECGVGKLD |
| | FEMMEV |
| SEQ. ID 59 | MIEMARYQC- |
| | MCGWVYDEDKGEPSQNIPPGTKFEDLPDTFREPQCGLGKNAFRKID- |
| SEQ. ID 60 | M--- |
| | AKWVCKICGYIYDEDAGDPDNGISPGTKFEELPDDWVEPICGAPKSEF |
| | EKLED |
| SEQ. ID 61 | M---QKYVCNVCGYEYDPAEH------- |
| | DNVPFDQLPDDWCCPVEGVSKDQFSPA-- |
| SEQ. ID 62 | M--- |
| | QKYVCDICGYVYDPEVGDPDGGINPGTAFEDIPEDWVCPLEGVGKED |
| | FSPE-D |
| SEQ. ID 63 | M--- |
| | KRYECIVCGWIYDEELGCPEEGIAPGTKWDDIPDDWTCPEEGVGKLD |
| | FEMMEV |
| SEQ. ID 64 | MIEMARYQC- |
| | MCGWVYDEDKGEPSQNIPPGTKFEDLPDTFRCPQEGLGKNAFRKID- |
| SEQ. ID 65 | M--- |
| | AKWVCKICGYIYDEDAGDPDNGISPGTKFEELPDDWVCPIEGAPKSEF |
| | EKLED |
| SEQ. ID 66 | M---QKYVSNVCGYEYDPAEH------- |
| | DNVPFDQLPDDWCCPVCGVSKDQFSPA-- |
| SEQ. ID 67 | M--- |
| | QKYVSDICGYVYDPEVGDPDGGINPGTAFEDIPEDWVCPLCGVGKED |
| | FSPE-D |
| SEQ. ID 68 | M--- |
| | KRYESIVCGWIYDEELGCPEEGIAPGTKWDDIPDDWTCPECGVGKLD |
| | FEMMEV |
| SEQ. ID 69 | MIEMARYQS- |
| | MCGWVYDEDKGEPSQNIPPGTKFEDLPDTFRCPQCGLGKNAFRKID- |
| SEQ. ID 70 | M--- |
| | AKWVSKICGYIYDEDAGDPDNGISPGTKFEELPDDWVCPICGAPKSEF |
| | EKLED |
| SEQ. ID 71 | M---QKYVCNVSGYEYDPAEH------- |
| | DNVPFDQLPDDWCCPVCGVSKDQFSPA-- |
| SEQ. ID 72 | M--- |
| | QKYVCDISGYVYDPEVGDPDGGINPGTAFEDIPEDWVCPLCGVGKED |
| | FSPE-D |
| SEQ. ID 73 | M--- |
| | KRYECIVSGWIYDEELGCPEEGIAPGTKWDDIPDDWTCPECGVGKLD |
| | FEMMEV |
| SEQ. ID 74 | MIEMARYQC- |
| | MSGWVYDEDKGEPSQNIPPGTKFEDLPDTFRCPQCGLGKNAFRKID- |
| SEQ. ID 75 | M--- |
| | AKWVCKISGYIYDEDAGDPDNGISPGTKFEELPDDWVCPICGAPKSEF |
| | EKLED |
| SEQ. ID 76 | M---QKYVCNVCGYEYDPAEH------- |
| | DNVPFDQLPDDWCSPVCGVSKDQFSPA-- |
| SEQ. ID 77 | M--- |
| | QKYVCDICGYVYDPEVGDPDGGINPGTAFEDIPEDWVSPLCGVGKED |
| | FSPE-D |
| SEQ. ID 78 | M--- |
| | KRYECIVCGWIYDEELGCPEEGIAPGTKWDDIPDDWTSPECGVGKLD |
| | FEMMEV |
| SEQ. ID 79 | MIEMARYQC- |
| | MCGWVYDEDKGEPSQNIPPGTKFEDLPDTFRSPQCGLGKNAFRKID- |
| SEQ. ID 80 | M--- |
| | AKWVCKICGYIYDEDAGDPDNGISPGTKFEELPDDWVSPICGAPKSEF |
| | EKLED |
| SEQ. ID 81 | M---QKYVCNVCGYEYDPAEH------- |
| | DNVPFDQLPDDWCCPVSGVSKDQFSPA-- |
| SEQ. ID 82 | M--- |
| | QKYVCDICGYVYDPEVGDPDGGINPGTAFEDIPEDWVCPLSGVGKED |
| | FSPE-D |
| SEQ. ID 83 | M--- |
| | KRYECIVCGWIYDEELGCPEEGIAPGTKWDDIPDDWTCPESGVGKLD |
| | FEMMEV |
| SEQ. ID 84 | MIEMARYQC- |
| | MCGWVYDEDKGEPSQNIPPGTKFEDLPDTFRCPQSGLGKNAFRKID- |
| SEQ. ID 85 | M--- |
| | AKWVCKICGYIYDEDAGDPDNGISPGTKFEELPDDWVCPISGAPKSEF |
| | EKLED |
| SEQ. ID 86 | M---QKYVANVCGYEYDPAEH------- |
| | DNVPFDQLPDDWCCPVCGVSKDQFSPA-- |
| SEQ. ID 87 | M--- |
| | QKYVADICGYVYDPEVGDPDGGINPGTAFEDIPEDWVCPLCGVGKED |
| | FSPE-D |
| SEQ. ID 88 | M--- |
| | KRYEAIVCGWIYDEELGCPEEGIAPGTKWDDIPDDWTCPECGVGKLD |
| | FEMMEV |
| SEQ. ID 89 | MIEMARYQA- |
| | MCGWVYDEDKGEPSQNIPPGTKFEDLPDTFRCPQCGLGKNAFRKID- |
| SEQ. ID 90 | M--- |
| | AKWVAKICGYIYDEDAGDPDNGISPGTKFEELPDDWVCPICGAPKSEF |
| | EKLED |
| SEQ. ID 91 | M---QKYVCNVAGYEYDPAEH------- |
| | DNVPFDQLPDDWCCPVCGVSKDQFSPA-- |
| SEQ. ID 92 | M--- |
| | QKYVCDIAGYVYDPEVGDPDGGINPGTAFEDIPEDWVCPLCGVGKED |
| | FSPE-D |
| SEQ. ID 93 | M--- |
| | KRYECIVAGWIYDEELGCPEEGIAPGTKWDDIPDDWTCPECGVGKLD |
| | FEMMEV |
| SEQ. ID 94 | MIEMARYQC- |
| | MAGWVYDEDKGEPSQNIPPGTKFEDLPDTFRCPQCGLGKNAFRKID- |
| SEQ. ID 95 | M--- |
| | AKWVCKIAGYIYDEDAGDPDNGISPGTKFEELPDDWVCPICGAPKSEF |
| | EKLED |
| SEQ. ID 96 | M---QKYVCNVCGYEYDPAEH------- |
| | DNVPFDQLPDDWCAPVCGVSKDQFSPA-- |
| SEQ. ID 97 | M--- |
| | QKYVCDICGYVYDPEVGDPDGGINPGTAFEDIPEDWVAPLCGVGKED |
| | FSPE-D |
| SEQ. ID 98 | M--- |
| | KRYECIVCGWIYDEELGCPEEGIAPGTKWDDIPDDWTAPECGVGKLD |
| | FEMMEV |
| SEQ. ID 99 | MIEMARYQC- |
| | MCGWVYDEDKGEPSQNIPPGTKFEDLPDTFRAPQCGLGKNAFRKID- |
| SEQ. ID | M--- |
| 100 | AKWVCKICGYIYDEDAGDPDNGISPGTKFEELPDDWVAPICGAPKSEF |
| | EKLED |
| SEQ. ID | M---QKYVCNVCGYEYDPAEH------- |
| 101 | DNVPFDQLPDDWCCPVAGVSKDQFSPA-- |
| SEQ. ID | M--- |
| 102 | QKYVCDICGYVYDPEVGDPDGGINPGTAFEDIPEDWVCPLAGVGKED |
| | FSPE-D |
| SEQ. ID | M--- |
| 103 | KRYECIVCGWIYDEELGCPEEGIAPGTKWDDIPDDWTCPEAGVGKLD |
| | FEMMEV |
| SEQ. ID | MIEMARYQC- |
| 104 | MCGWVYDEDKGEPSQNIPPGTKFEDLPDTFRCPQAGLGKNAFRKID- |
| SEQ. ID | M--- |
| 105 | AKWVCKICGYIYDEDAGDPDNGISPGTKFEELPDDWVCPIAGAPKSEF |
| | EKLED |

In some embodiments, the rubredoxin polypeptide comprises a polypeptide having at least 7000, at least 7500, at least 8000, at least 85%, at least 90%, or at least 95% homology to any one of SEQ. ID 1-SEQ. ID 105.

In some embodiments, the rubredoxin polypeptide comprises a polypeptide of any one of SEQ. ID 1-SEQ. ID 105.

In some embodiments, the non-native metal is not Ni, Co, Zn, Cd, Hg, Ga, Cu, or Mo.

In some embodiments, the non-native metal bound within the coordination environment comprises a low spin metal complex.

In some embodiments, the non-native metal is cobalt.

In some embodiments, the non-native metal is titanium.

In some embodiments, the non-native metal is manganese.

In some embodiments, the non-native metal is molybdenum (e.g., Mo(V)). In certain embodiments, the metal-substituted rubredoxin polypeptide comprises Mo(V)-rubredoxin.

In some embodiments, the non-native metal is vanadium (e.g., V(IV)). In certain embodiments, the metal-substituted rubredoxin polypeptide comprises vanadyl-rubredoxin ((V═O)-rubredoxin).

In some embodiments, the metal-substituted rubredoxin polypeptide is stable up to at least 77 K, as indicated by continuous-wave electron paramagnetic resonance (cwEPR).

The metal-substituted metalloproteins described herein and the metal-substituted rubredoxin polypeptides described herein can be immobilized on a surface. The metal-substituted metalloproteins described herein and the metal-substituted rubredoxin polypeptides described herein can be covalently attached to a triazatriangulene. The metal-substituted metalloproteins described herein and the metal-substituted rubredoxin polypeptides described herein can be covalently attached to a surface.

In certain embodiments, the surface comprises a semiconductor surface. In certain embodiments, the surface comprises graphene (e.g., graphene-MoS₂).

Also provided herein are systems comprising a periodic array of the metal-substituted metalloproteins described herein or the metal-substituted rubredoxin polypeptides described herein immobilized on a surface. In some embodiments, the metal-substituted metalloproteins described herein or the metal-substituted rubredoxin polypeptides can be covalently attached to the surface.

In certain embodiments, the surface comprises a semiconductor surface. In certain embodiments, the surface comprises graphene (e.g., graphene-MoS₂).

Also provided herein are quantum information processing platforms that comprise the metal-substituted metalloproteins described herein or the metal-substituted rubredoxin polypeptides described herein. In certain embodiments, the metal-substituted metalloproteins described herein or the metal-substituted rubredoxin polypeptides described herein can function as qubits and/or qudits within the quantum information processing platform. In certain embodiments, the quantum information processing platform can comprise a periodic array of the metal-substituted metalloproteins described herein or the metal-substituted rubredoxin polypeptides described herein immobilized on a surface. In certain embodiments, the surface comprises a semiconductor surface. In certain embodiments, the surface comprises graphene (e.g., graphene-MoS₂). Quantum information processing platforms are known in the art, and are described, for example, in U.S. Pat. No. 7,219,018, which is incorporated herein by reference in its entirety.

### EXAMPLES

The following examples are put forth so as to provide those of ordinary skill in the art with a complete disclosure and description of how the compounds, compositions, articles, devices and/or methods claimed herein are made and evaluated, and are intended to be purely exemplary and are not intended to limit the disclosure. Efforts have been made to ensure accuracy with respect to numbers (e.g., amounts, temperature, etc.), but some errors and deviations should be accounted for. Unless indicated otherwise, parts are parts by weight, temperature is in ° C. or is at ambient temperature, and pressure is at or near atmospheric

### Example 1: Vanadium-Substituted Proteins as Molecular Qubits

### Summary

Quantum information storage and processing represent critical areas in emergent materials research, with molecular qubits offering great promise due to their tunability, homogeneity, and facile integration into ordered arrays and materials. The use of proteins as ligand scaffolds for electron spin-based qubits is underexplored and brings distinct advantages, including production scalability, magnetic site isolation, and the possibility for distal array attachment sites. In this Example, the incorporation of d1 vanadium(IV) and vanadyl ([V═O]2+) ions into metalloprotein active sites is proposed as an approach for the generation of molecular electron spin qubits. The suitability of diverse metalloprotein scaffolds for harboring V(IV) centers that feature long coherence lifetimes and slow longitudinal relaxation will be assessed using pulsed electron paramagnetic resonance spectroscopy. These scaffolds will be coupled to heterogeneous surfaces or arrays in a well-defined manner for characterization within the context of quantum information science, and, ultimately, downstream integration of optical triggers for initialization or readout will be pursued. This work combines biology, inorganic chemistry, and spin physics to generate a proof-of-concept prototype for protein-based molecular qubits for quantum information applications.

### Introduction

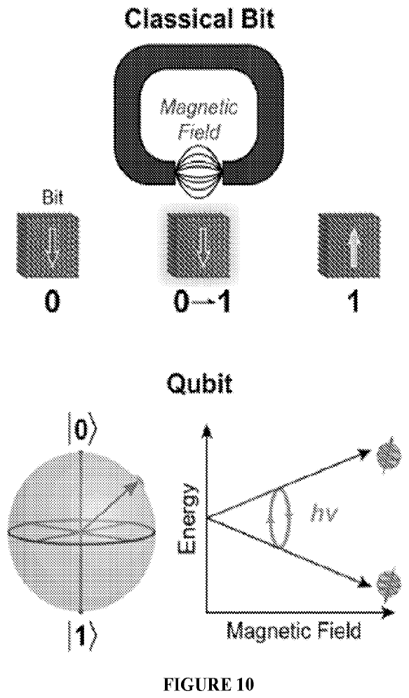

The field of quantum information science (QIS) is exploding, with commercial technology available for running computations and grand opportunities heralded for quantum cryptography and quantum networking. At the core of all quantum computers, and thus underpinning all of these future developments, is the quantum bit, or “qubit”. Unlike a conventional bit, a qubit can exist in a superposition of states and can be entangled with other qubits, leading to counterintuitive phenomena like quantum teleportation (the foundation for quantum communication) and new approaches to computing that yield a ‘quantum advantage’ when compared to classical computers (FIG. 10).

Current state-of-the-art qubits include trapped lanthanide ions (e.g., the company IonQ uses Yb ions within an optical trap), electronic defect sites in solid state materials (e.g., nitrogen vacancy sites in diamond), or semiconductor nanostructures (e.g., silicon quantum dots). Molecules have been touted as the “qubit of the future” and chemists called to arms because of the many opportunities that molecular qubits could provide over these traditional systems. Specifically, molecular qubits offer three distinct advantages: (1) Highly resolved tunability of the spin system through molecular design; (2) Established methods for precise positioning into ordered arrays for macroscopic organization; (3) Reproducible strategies for producing large quantities (~1023) of atomically identical qubits. In addition, molecular systems can have more than two accessible spin states and states that couple electron and nuclear spins, forming d-dimensional “qudits” in a spin system with more than one unpaired electron and/or spin-active nuclei. Despite these advantages, molecular qubits have yet to be commercially realized owing to a few key limitations, including coherence (T2) and spin-lattice (T1) lifetimes that are too short and limited strategies for optical preparation and/or readout. To address some of the shortcomings of traditional small molecule qubits, we propose the development and characterization of vanadium-substituted proteins as qubit candidates.

The use of proteins as ligand scaffolds for electron spin-based qubits is underexplored, with few previous reports. Most efforts in molecular qubit design have focused on small synthetic compounds featuring complex ligand architectures and empirical solvent selection processes. However, proteins offer valuable inherent advantages for qubit construction,
including magnetic site isolation to extend T1 relaxation lifetimes, a high degree of electronic tunability and facile access to asymmetric secondary coordination spheres to enhance T2 lifetimes, production scalability, and the possibility for distal array attachment sites.

This Example combines biology, inorganic chemistry, and spin physics to generate new systems for quantum information applications.

### Specific Objectives

(1) Incorporate vanadium(IV) and vanadyl ([V═O]²⁺) ions into the active sites of a small library of naturally occurring metalloproteins.
(2) Characterize the coherence and spin-lattice relaxation times of V(IV) metalloproteins using variable-temperature continuous wave and pulsed EPR spectroscopy.
(3) Attach V(IV) metalloprotein candidates to surfaces in an ordered manner and characterize using microscopy and EPR.

### Research Plan: Description and Methodology

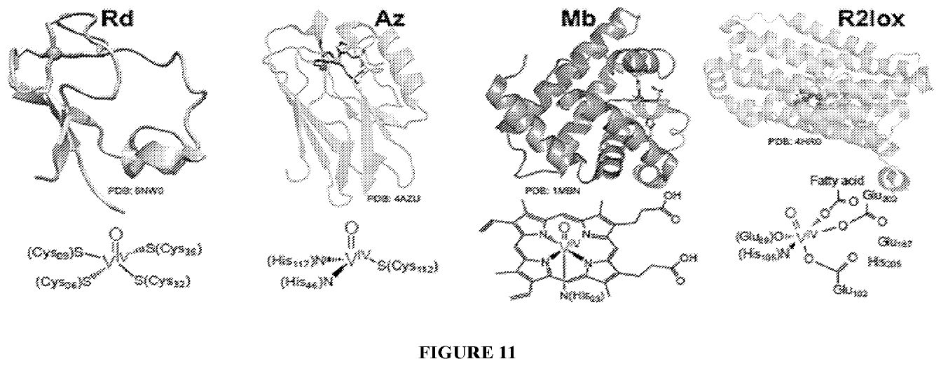

Incorporation of vanadium(IV) and vanadyl ([V═O]²⁺) ions into metalloprotein active sites. Initial work will establish feasibility through developing a small library of vanadium-substituted proteins. Our group has considerable expertise in the design and production of artificial metalloenzymes that utilize non-natural metal substitution within existing metalloprotein scaffolds. As a result, we have at our disposal a library of robust metalloproteins and mutants to use as a platform for discovery, including rubredoxin (Rd), azurin (Az), myoglobin (Mb), and R2-like ligand binding oxidase (R2|ox) (FIG. 11). We can incorporate a range of non-native metals into these scaffolds, including introducing nickel into the Rd iron site, introducing iron into the R2|ox manganese site, and introducing nickel into the Az copper site.

[V═O]²⁺ is often used as a surrogate for Fe²⁺, and most of these proteins readily bind Fe²⁺ upon extraction of the native metal. Preliminary data suggests we can incorporate V(II) into Az and retain metal-centered redox activity, with the potential to access the V(IV) state in the future. In addition, vanadyl-substituted metalloporphyrins can be incorporated into heme proteins, such as Mb.

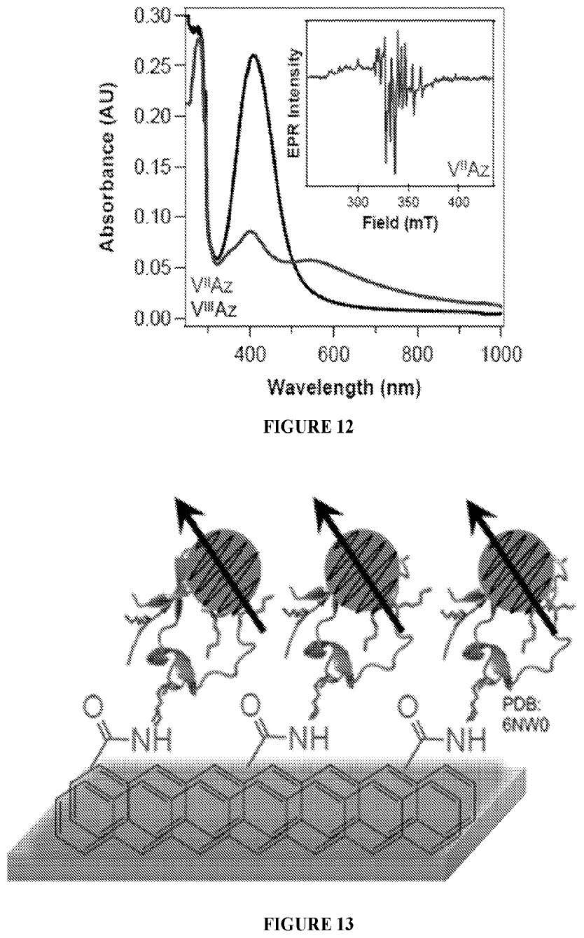

Vanadium(IV) and vanadyl incorporation was pursued in a combinatorial manner, using 96-well plates loaded with metal-free protein across different buffers and pHs and adding an array of different metal salts. Metal binding was assessed initially using optical spectroscopy, using a plate reader to identify any new electronic transitions. For example, we have used UV-Vis spectroscopy for characterizing V(II) binding to apo-Az (FIG. 12). Promising hits were optimized using meso-scale reactions (~1 mL), which will provide sufficient samples for thorough optical and EPR studies.

Characterization the coherence and spin-lattice relaxation times of V(IV) metalloproteins using variable-temperature continuous wave and pulsed EPR spectroscopy. Proteins that bind V(IV) or [V═O]²⁺ were further characterized using magnetic resonance techniques. Continuous wave (CW) EPR spectroscopy on V(IV) and [V═O]²⁺-bound proteins was used initially to identify candidates suitable for pulsed experimentation. Because V(IV) is a d1 ion that typically couples to the I=7/2 V nucleus, and the spectral properties have been benchmarked across hundreds of small-molecule compounds, we are able to extract information about the protein coordination environment from the simulated EPR parameters, as demonstrated from our preliminary V-Az studies (FIG. 12, inset). Relative relaxation rates across the V-bound proteins were established through power- and temperature-dependent saturation studies using CW instrumentation, and the most promising candidates were subjected to variable-temperature pulsed EPR measurements to establish the T1 and T2 values. It has been demonstrated that eliminating nuclear spins from ligand scaffolds decreases relaxation rates significantly, to the point of extending T2 to ~1 s at 100 K and ~1 ms at 10 K for a [V(IV)(C₃S₈)₃]²⁻ compound with deuterated counterions and in CS₂ solvent. Given this, V-Rd or VO-Rd exhibited the longest coherence lifetimes, as the protein ligation occurs through spin-free nuclei (i.e., S-atoms in the primary sphere with proximal C-atoms). We have also demonstrated 2H incorporation into the Rd protein using isotopically labeled growth media for NMR experiments, and anticipate that global deuteration of both the protein and the solvent will further increase T2. While site isolation is typically accomplished in synthetic compounds through dilution into a diamagnetic matrix, the protein scaffolds used here are approximately an order of magnitude larger than the synthetic compounds studied. Moreover, most protein active sites are buried within the protein scaffold to promote electron transfer and/or selective substrate reactivity. Thus, the solvent-excluded active site can serve to provide site isolation without requiring an additional component. This site isolation represents an advantage of our approach-using existing stable metalloprotein scaffolds-over incorporation of a paramagnetic ion into small peptides.

We are also interested in whether we can observe Rabi oscillations in the V-bound proteins. Rabi oscillations are measured through microwave nutation experiments and report on the optimal microwave pulse length for achieving complete inversion of the spin packet; the presence of oscillations also indicates the ability to place the qubit in an arbitrary superposition of states. In quantum computing, the time between the Rabi oscillations is equivalent to the length of the NOT gate, and the ratio between T2 and the Rabi oscillation frequency corresponds to the maximum number of spin-flip operations that could be performed for a given qubit (QM), giving a useful figure of merit. As V-Az is readily observed in EPR measurements up to ~80 K, indicative of relatively slow relaxation, we anticipate accessing high QM values across different mutants.

Attachment of V(IV) metalloprotein candidates to surfaces in an ordered manner and characterization using microscopy and EPR. Another advantage of using protein scaffolds as qubits is the ability to couple the protein to surfaces in a well-defined, site-selective manner. We have demonstrated site-selective coupling to electrode surfaces across multiple modalities within the Rd system (FIG. 13), showing variation in interfacial electron transfer rates depending on the coupling method. We can utilize many of those same attachment approaches and mutants to covalently couple a protein-based qubit to an ordered array. As an example, metalloproteins can be coupled to highly oriented pyrolytic graphite surfaces as a model for carbon nanostructures. We have demonstrated that
manipulation of the distal protein residues does not perturb the metal-binding site in the example metalloproteins described above. Accordingly, we can independently tune the qubit properties (e.g., the coordination environment surrounding the metal and attachment modalities.

Characterization was carried out using AFM and SEM microscopy techniques along with EPR of the surfacebound protein. The EPR measurements are important to establish that surface attachment does not perturb the magnetic properties, an ongoing challenge in the field of molecular magnets. V-bound proteins can also be incorporated site-selectively into MOFs and onto lithographically deposited conducting surfaces.

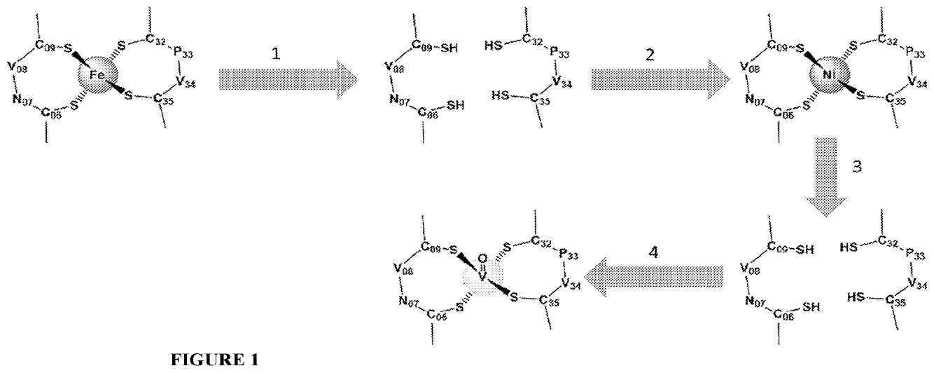

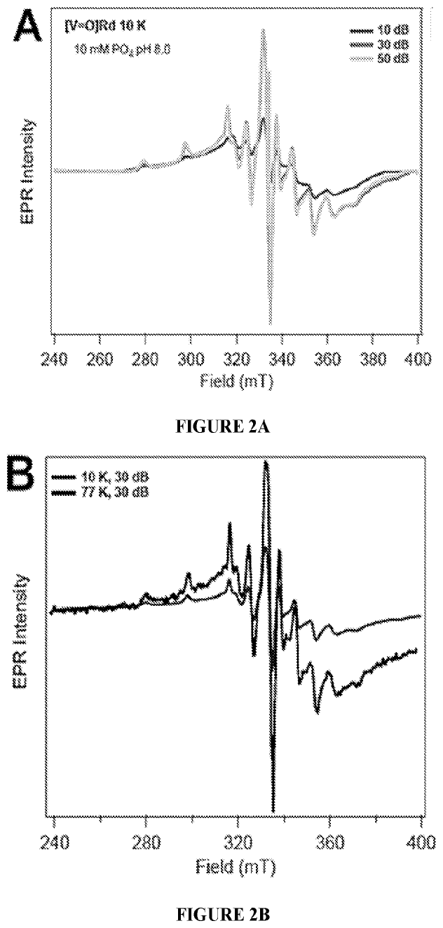

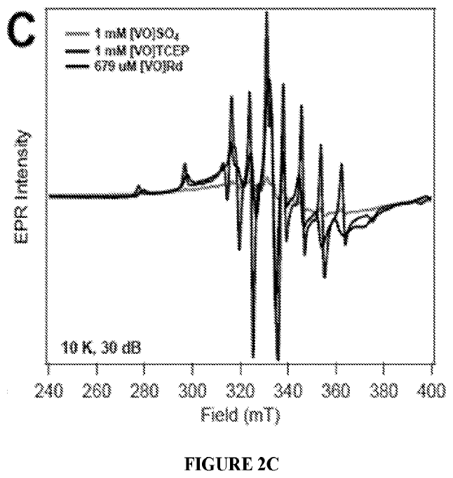

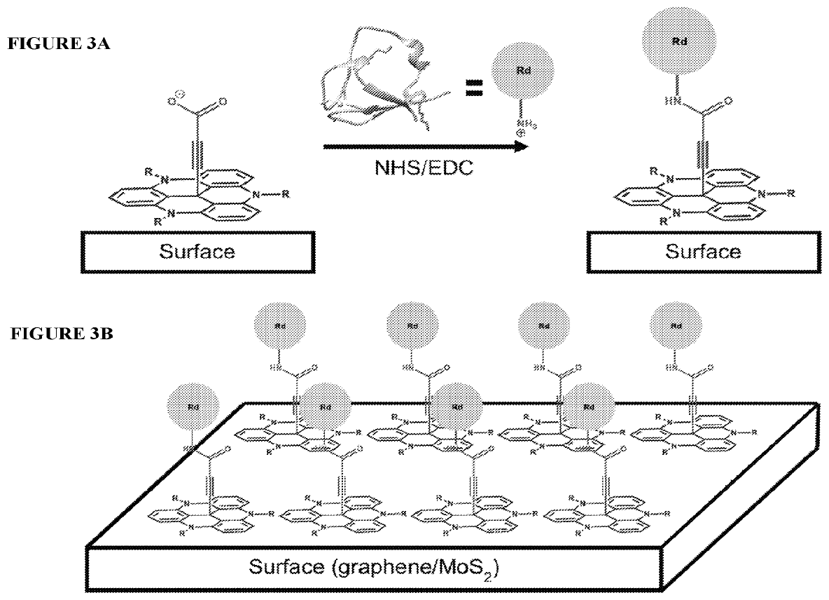

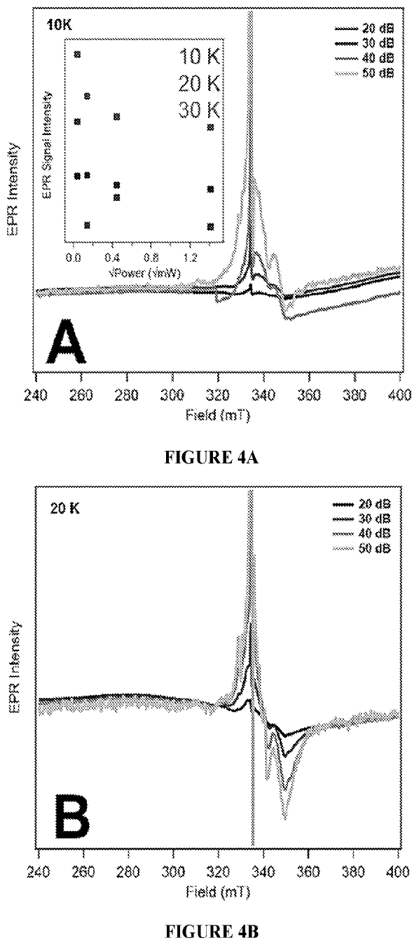

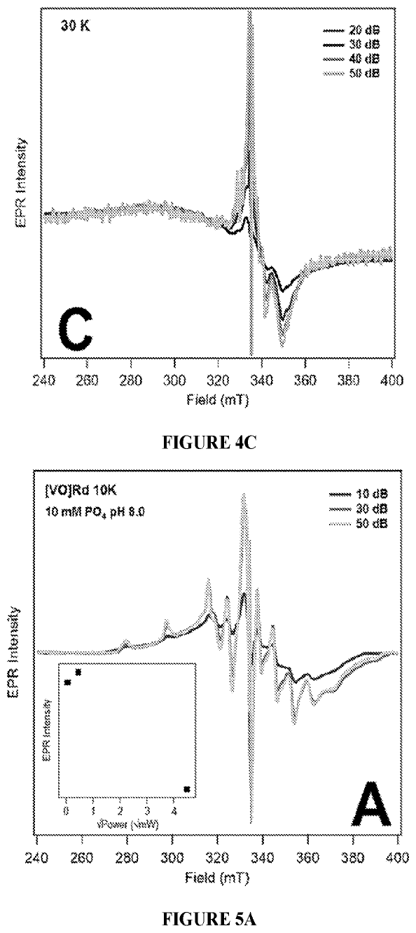

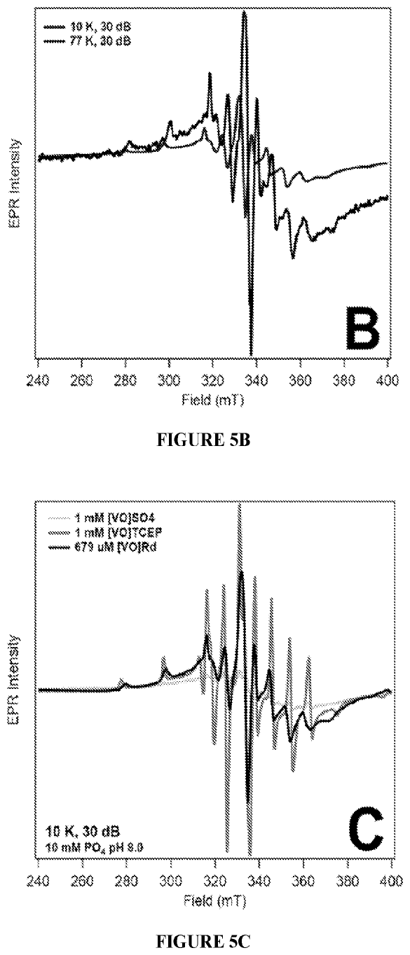

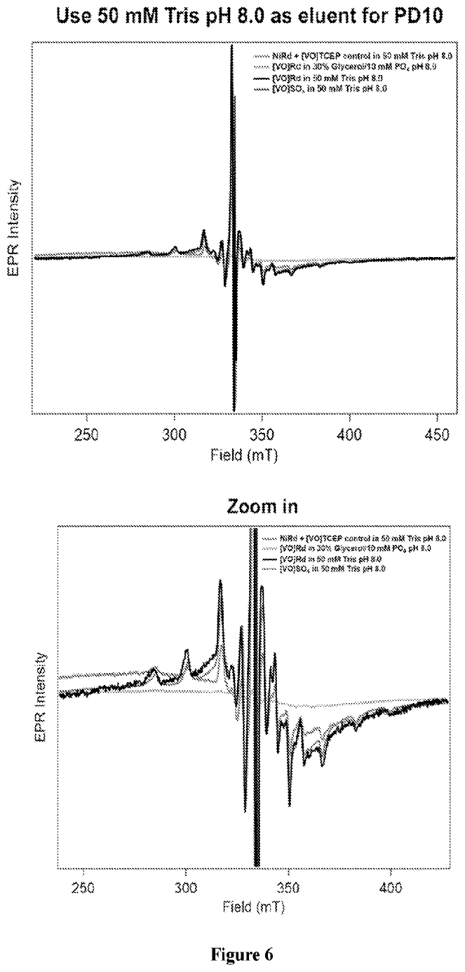

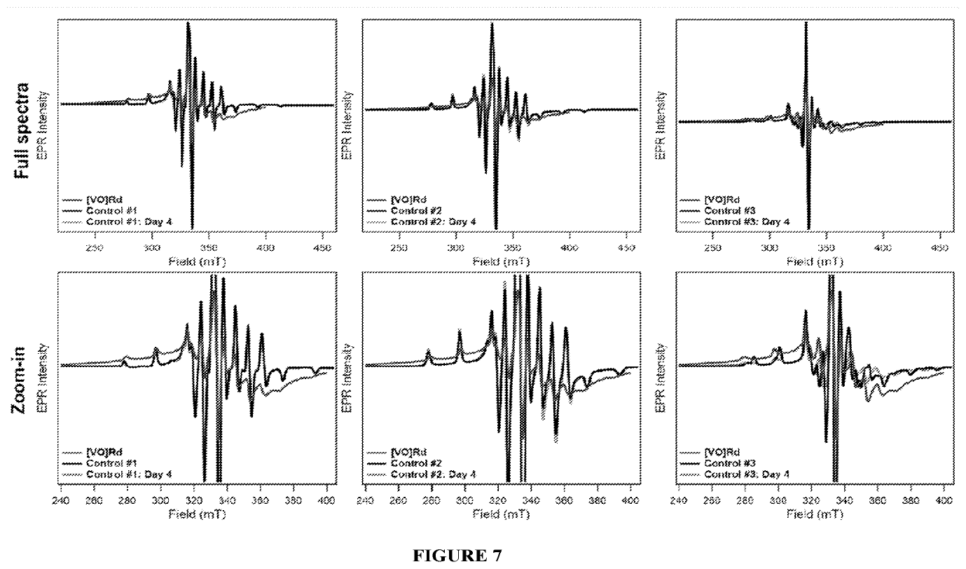

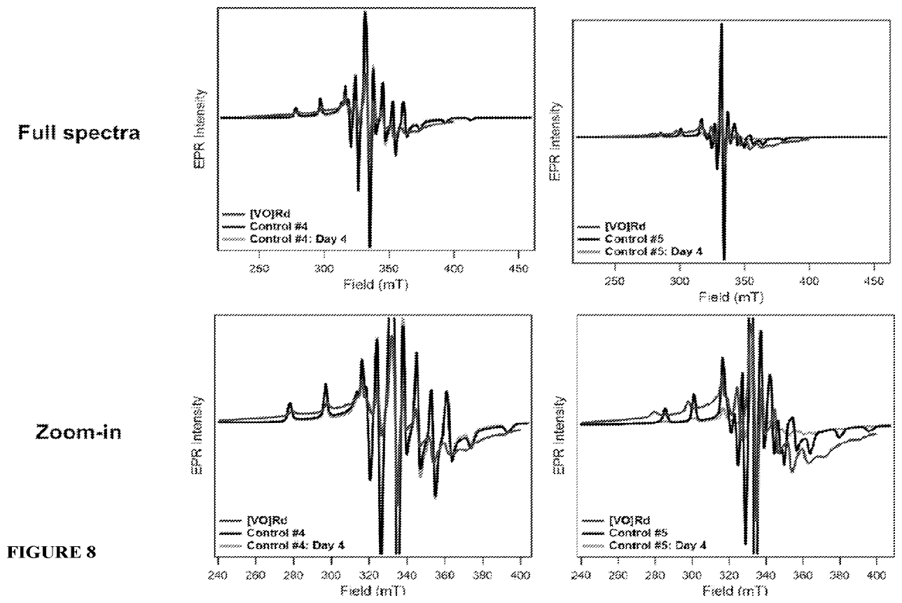

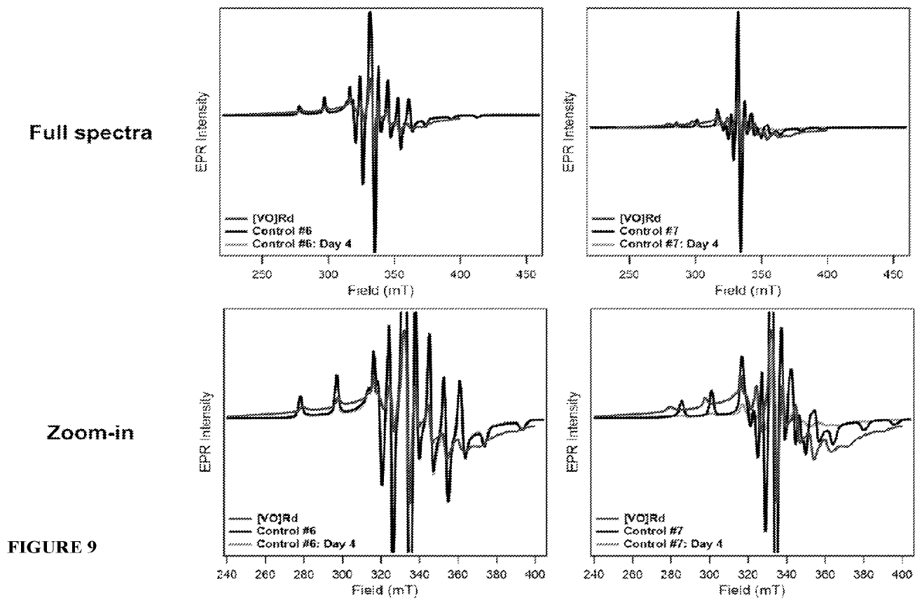

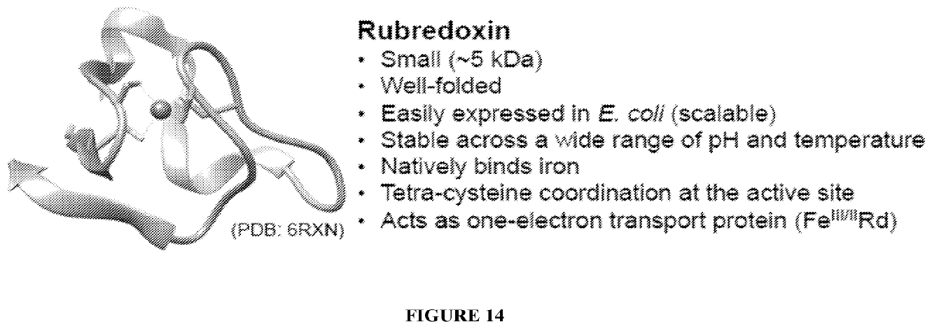

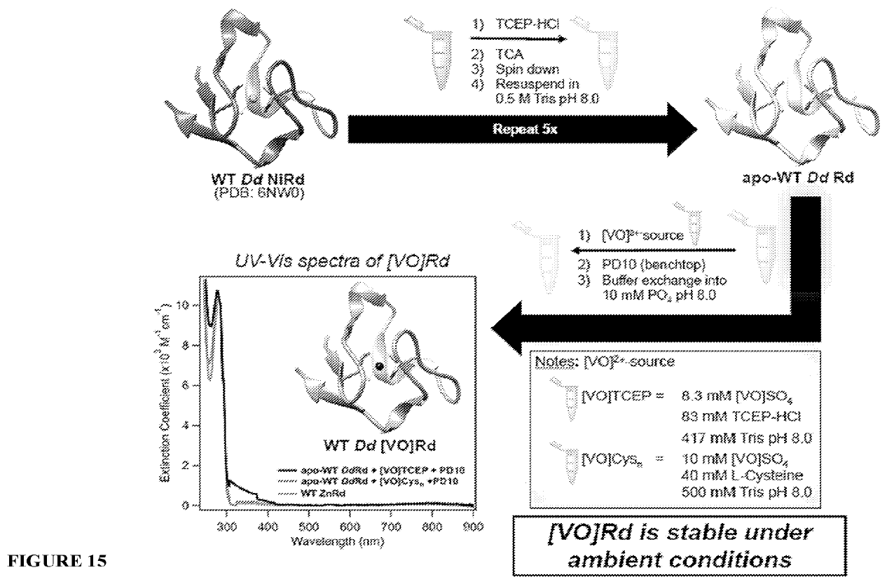

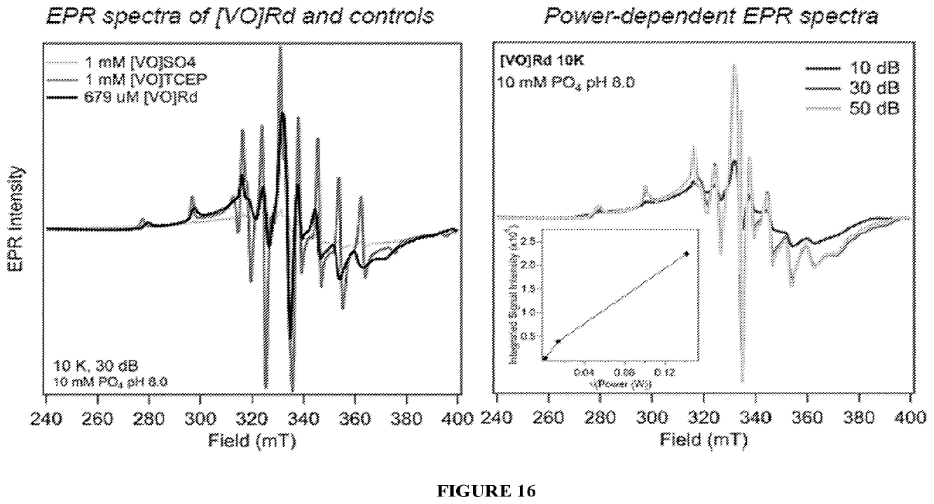

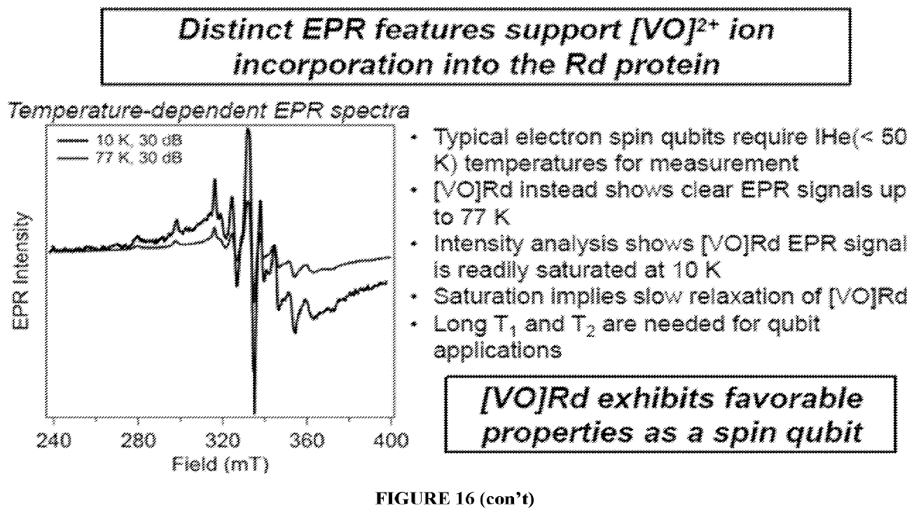

Using these strategies, we have prepared example vanadium-bound metalloproteins and assessed their viability as molecular qubit candidates through pulsed EPR measurements. Further results are described in FIGS. 1-9 and FIGS. 14-16. Comparison of the quantum properties across mutants and different protein scaffolds allows us to establish a correlation between coordination environment and spin system behavior, providing design principles for further optimization and establishing the viability of this approach for future investment.

### REFERENCES

(1) Feynman, R. P. Simulating physics with computers. International Journal of Theoretical Physics 1982, 21, 467-488.
(2) Aspuru-Guzik, A.; Dutoi, A. D.; Love, P. J.; Head-Gordon, M. Simulated Quantum Computation of Molecular Energies. Science 2005, 309, 1704-1707.
(3) Pagano, G.; Hess, P. W.; Kaplan, H. B.; Tan, W. L.; Richerme, P.; Becker, P.; Kyprianidis, A.; Zhang, J.; Birckelbaw, E.; Hernandez, M. R.; Wu, Y.; Monroe, C. Cryogenic trapped-ion system for large scale quantum simulation. Quantum Science and Technology 2018, 4, 014004.
(4) Doherty, M. W.; Manson, N. B.; Delaney, P.; Jelezko, F.; Wrachtrup, J.; Hollenberg, L. C. L. The nitrogen-vacancy colour centre in diamond. Physics Reports 2013, 528, 1-45.
(5) Maurand, R.; Jehl, X.; Kotekar-Patil, D.; Coma, A.; Bohuslavskyi, H.; Laviéville, R.; Hutin, L.; Barraud, S.; Vinet, M.; Sanquer, M.; De Franceschi, S. A CMOS silicon spin qubit. Nature Communications 2016, 7, 13575.
(6) Graham, M. J.; Zadrozny, J. M.; Fataftah, M. S.; Freedman, D. E. Forging Solid-State Qubit Design Principles in a Molecular Furnace. Chemistry of Materials 2017, 29, 1885-1897.
(7) Wasielewski, M. R.; Forbes, M. D. E.; Frank, N. L.; Kowalski, K.; Scholes, G. D.; Yuen-Zhou, J.; Baldo, M. A.; Freedman, D. E.; Goldsmith, R. H.; Goodson, T.; Kirk, M. L.; McCusker, J. K.; Ogilvie, J. P.; Shultz, D. A.; Stoll, S.; Whaley, K. B. Exploiting chemistry and molecular systems for quantum information science. Nature Reviews Chemistry 2020.
(8) Yu, C.-J.; von Kugelgen, S.; Laorenza, D. W.; Freedman, D. E. A Molecular Approach to Quantum Sensing. ACS Central Science 2021.
(9) Gimeno, I.; Urtizberea, A.; Román-Roche, J.; Zueco, D.; Cam6n, A.; Alonso, P. J.; Roubeau, O.; Luis, F. Broad-band spectroscopy of a vanadyl porphyrin: a model electronuclear spin qudit. Chemical Science 2021, 12, 5621-5630.
(10) Atzori, M.; Garlatti, E.; Allodi, G.; Chicco, S.; Chiesa, A.; Albino, A.; De Renzi, R.; Salvadori, E.; Chiesa, M.; Carretta, S.; Sorace, L. Radiofrequency to Microwave Coherent Manipulation of an Organometallic Electronic Spin Qubit Coupled to a Nuclear Qudit. Inorganic Chemistry 2021.
(11) Yu, C.-J.; Graham, M. J.; Zadrozny, J. M.; Niklas, J.; Krzyaniak, M. D.; Wasielewski, M. R.; Poluektov, O. G.; Freedman, D. E. Long Coherence Times in Nuclear Spin-Free Vanadyl Qubits. Journal of the American Chemical Society 2016, 138, 14678-14685.
(12) Rosaleny, L. E.; Cardona-Serra, S.; Escalera-Moreno, L.; Baldovi, J. J.; Golebiewska, V.; Wlazlo, K.; Casino, P.; Prima-Garcia, H.; Gaita-Arino, A.; Coronado, E. Peptides as Versatile Platforms for Quantum Computing. The Journal of Physical Chemistry Letters 2018, 9, 4522-4526.
(13) Zadrozny, J. M.; Niklas, J.; Poluektov, O. G.; Freedman, D. E. Millisecond Coherence Time in a Tunable Molecular Electronic Spin Qubit. ACS Central Science 2015, 1, 488-492.
(14) Atzori, M.; Morra, E.; Tesi, L.; Albino, A.; Chiesa, M.; Sorace, L.; Sessoli, R. Quantum Coherence Times Enhancement in Vanadium(IV)-based Potential Molecular Qubits: the Key Role of the Vanadyl Moiety. Journal of the American Chemical Society 2016, 138, 11234-11244.
(15) Eaton, G. R.; Eaton, S. S. Relaxation times of organic radicals and transition metal ions. In Distance Measurements in Biological Systems by EPR; Berliner, L. J., Eaton, G. R., Eaton, S. S., Eds.; Kluwer Academic Plenum Publishers: New York, New York, 2000; Vol. 19, pp 29-154.
(16) Brya, W. J.; Wagner, P. E. Direct, Orbach, and Raman Relaxation in Dilute Cerous Magnesium Nitrate. Physical Review 1966, 147, 239-241.
(17) Reynhardt, E. C. Spin lattice relaxation of spin-1 nuclei in solids containing diluted paramagnetic impurity centers. I. Zeeman polarization of nuclear spin system. Concepts in Magnetic Resonance Part A 2003, 19A, 20-3 5.
(18) Lu, Y.; Garner, D. K.; Zhang, J. Artificial Metalloproteins: Design and Engineering. In Wiley Encyclopedia of Chemical Biology; American Cancer Society, 2008; pp 1-10.
(19) Waugh, M. W.; Dwaraknath, S.; Lu, Y. Advances in Metalloprotein Design and Engineering: Strategies Employed and Insights Gained. In Comprehensive Coordination Chemistry III; Elsevier, 2021; pp 900-928.
(20) Trevino, R. E.; Slater, J. W.; Shafaat, H. S. Robust Carbon-Based Electrodes for Hydrogen Evolution through Site-Selective Covalent Attachment of an Artificial Metalloenzyme. ACS Applied Energy Materials 2020, 3, 11099-11112 DOI: 10.1021/acsaem.0c02069.
(21) Slater, J. W.; Marguet, S. C.; Monaco, H. A.; Shafaat, H. S. Going beyond Structure: Nickel-Substituted Rubredoxin as a Mechanistic Model for the [NiFe] Hydrogenases. Journal of the American Chemical Society 2018, 140, 10250-10262.
(22) Slater, J. W.; Marguet, S. C.; Gray, M. E.; Monaco, H. A.; Sotomayor, M.; Shafaat, H. S. Power of the Secondary Sphere: Modulating Hydrogenase Activity in Nickel-Substituted Rubredoxin. ACS Catalysis 2019, 9, 8928-8942.
(23) Miller, E. K.; Trivelas, N. E.; Maugeri, P. T.; Blaesi, E. J.; Shafaat, H. S. Time-Resolved Investigations of Heterobimetallic Cofactor Assembly in R2lox Reveal Distinct Mn/Fe Intermediates. Biochemistry 2017, 56, 3369-3379.
(24) Manesis, A. C.; O'Connor, M. J.; Schneider, C. R.; Shafaat, H. S. Multielectron Chemistry within a Model Nickel Metalloprotein: Mechanistic Implications for Acetyl-CoA Synthase. Journal of the American Chemical Society 2017, 139, 10328-10338.
(25) Lewis, L. C.; Shafaat, H. S. Reversible Electron Transfer and Substrate Binding Support [NiFe3S₄] Ferredoxin as a Protein-Based Model for [NiFe] Carbon Monoxide Dehydrogenase. Inorganic Chemistry 2021, 60, 13869-13875.
(26) Slater, J. W.; Shafaat, H. S. Nickel-Substituted Rubredoxin as a Minimal Enzyme Model for Hydrogenase. The Journal of Physical Chemistry Letters 2015, 6, 3731-3736.
(27) Maugeri, P. T.; Griese, J. J.; Branca, R. M.; Miller, E. K.; Smith, Z. R.; Eirich, J.; Högbom, M.; Shafaat, H. S. Driving Protein Conformational Changes with Light: Photoinduced Structural Rearrangement in a Heterobimetallic Oxidase. Journal of the American Chemical Society 2018, 140, 1471-1480.
(28) Manesis, A. C.; Shafaat, H. S. Electrochemical, Spectroscopic, and Density Functional Theory Characterization of Redox Activity in Nickel-Substituted Azurin: A Model for Acetyl-CoA Synthase. Inorganic Chemistry 2015, 54, 7959-7967.
(29) Tamura, M.; Shimidzu, N.; Hayashi, K. Vanadium-substituted hemoproteins (I). Biochemical and Biophysical Research Communications 1977, 75, 1029-1036.
(30) Chasteen, N. D. Vanadyl(IV) EPR Spin Probes Inorganic and Biochemical Aspects. In Biological Magnetic Resonance; Berliner, L. J., Reuben, J., Eds.; Springer US: Boston, MA, 1981; pp 53-119.
(31) Martinie, R. J.; Pollock, C. J.; Matthews, M. L.; Bollinger, J. M.; Krebs, C.; Silakov, A. Vanadyl as a Stable Structural Mimic of Reactive Ferryl Intermediates in Mononuclear Nonheme-Iron Enzymes. Inorganic Chemistry 2017, 56, 13382-13389.
(32) Matthew P. McLaughlin; Retegan, M.; Bill, E.; Payne, T. M.; Shafaat, H. S.; Pena, S.; Sudhamsu, J.; Ensign, A. A.; Crane, B. R.; Neese, F.; Holland, P. L. Azurin as a Protein Scaffold for a Low-coordinate Nonheme Iron Site with a Small-molecule Binding Pocket. Journal of the American Chemical Society 2012, 134, 19746-19757.
(33) Griese, J. J.; Roos, K.; Cox, N.; Shafaat, H. S.; Branca, R. M. M.; Lehtio, J.; Graslund, A.; Lubitz, W.; Siegbahn, P. E. M.; Hogbom, M. Direct observation of structurally encoded metal discrimination and ether bond formation in a heterodinuclear metalloprotein. Proceedings of the National Academy of Sciences 2013, 110, 17189-17194.
(34) Maiti, B. K.; Maia, L. B.; Silveira, C. M.; Todorovic, S.; Carreira, C.; Carepo, M. S. P.; Grazina, R.; Moura, I.; Pauleta, S. R.; Moura, J. J. G. Incorporation of molybdenum in rubredoxin: models for mononuclear molybdenum enzymes. JBIC Journal of Biological Inorganic Chemistry 2015, 20, 821-829.
(35) Krzystek, J.; Ozarowski, A.; Telser, J.; Crans, D. C. High-frequency and -field electron paramagnetic resonance of vanadium(IV, III, and II) complexes. Coordination Chemistry Reviews 2015, 301-302, 123-133.
(36) Smith, T. S.; LoBrutto, R.; Pecoraro, V. L. Paramagnetic spectroscopy of vanadyl complexes and its applications to biological systems. Coordination Chemistry Reviews 2002, 228, 1-18.
(37) Pace, R. J.; Smith, P.; Bramley, R.; Stehlik, D. EPR saturation and temperature dependence studies on signals from the oxygen-evolving centre of photosystem II. Biochimica et Biophysica Acta (BBA)—Bioenergetics 1991, 1058, 161-170.
(38) Lund, A.; Sagstuen, E.; Sanderud, A.; Maruani, J. Relaxation-Time Determination from Continuous-Microwave Saturation of EPR Spectra. Radiation Research 2009, 172, 753-760.
(39) Hirsh, D. J.; Brudvig, G. W. Measuring distances in proteins by saturation-recovery EPR. Nature Protocols 2007, 2, 1770-1781.
(40) Culvahouse, J. W.; Richards, P. M. T 1 and T 2 for Orbach Relaxation Processes. Physical Review 1969, 178, 485.
(41) Schweiger, A. Creation and detection of coherence and polarization in pulsed EPR. Journal of the Chemical Society, Faraday Transactions 1995, 91, 177-190.
(42) Schweiger, A.; Jeschke, G. Principles of Pulse Electron Paramagnetic Resonance; Oxford University Press, 2001.
(43) Harmer, J.; Mitrikas, G.; Schweiger, A. Advanced Pulse EPR Methods for the Characterization of Metalloproteins. In High Resolution EPR; Berliner, L., Hanson, G., Eds.; Springer New York: New York, NY, 2009; Vol. 28, pp 13-61.
(44) Graham, M. J.; Yu, C.-J.; Krzyaniak, M. D.; Wasielewski, M. R.; Freedman, D. E. Synthetic Approach To Determine the Effect of Nuclear Spin Distance on Electronic Spin Decoherence. Journal of the American Chemical Society 2017, 139, 3196-3201.
(45) Fataftah, M. S.; Krzyaniak, M. D.; Vlaisavljevich, B.; Wasielewski, M. R.; Zadrozny, J. M.; Freedman, D. E. Metal-ligand covalency enables room temperature molecular qubit candidates. Chemical Science 2019, 10, 6707-6714.
(46) Lin, M. T.; Sperling, L. J.; Frericks Schmidt, H. L.; Tang, M.; Samoilova, R. I.; Kumasaka, T.; Iwasaki, T.; Dikanov, S. A.; Rienstra, C. M.; Gennis, R. B. A rapid and robust method for selective isotope labeling of proteins. Methods 2011, 55, 370-378.
(47) Lacabanne, D.; Fogeron, M.-L.; Wiegand, T.; Cadalbert, R.; Meier, B. H.; Bockmann, A. Protein sample preparation for solid-state NMR investigations. Progress in Nuclear Magnetic Resonance Spectroscopy 2019, 110, 20-33.
(48) Zadrozny, J. M.; Long, J. R. Slow Magnetic Relaxation at Zero Field in the Tetrahedral Complex [Co(SPh)₄]²⁻. Journal of the American Chemical Society 2011, 133, 20732-20734.
(49) Gray, H. B.; Winkler, J. R. Long-range electron transfer. Proceedings Of The National Academy Of Sciences Of The United States Of America 2005, 102, 3534-3539.
(50) Manley, O. M.; Makris, T. M. Cytochrome P450 Enzyme Mechanisms. In Comprehensive Coordination Chemistry III; Elsevier, 2021; pp 254-268.
(51) Zadrozny, J. M.; Niklas, J.; Poluektov, O. G.; Freedman, D. E. Multiple Quantum Coherences from Hyperfine Transitions in a Vanadium(IV) Complex. Journal of the American Chemical Society 2014, 136, 15841-15844.
(52) Cox, N.; Retegan, M.; Neese, F.; Pantazis, D. A.; Boussac, A.; Lubitz, W. Electronic structure of the oxygen-evolving complex in photosystem II prior to 0-0 bond formation. Science 2014, 345, 804-808.
(53) Feddes, B.; Kravchenko, I. I.; Seiberling, L. E. On superperiodic features on highly oriented pyrolytic graphite. Scanning 1998, 20, 376-379.
(54) Ghirri, A.; Corradini, V.; Cervetti, C.; Candini, A.; del Pennino, U.; Timco, G.; Pritchard, R. J.; Muryn, C. A.; Winpenny, R. E. P.; Affronte, M. Deposition of Functionalized Cr7Ni Molecular Rings on Graphite from the Liquid Phase. Advanced Functional Materials 2010, 20, 1552-1560.
(55) Blanford, C. F.; Armstrong, F. A. The pyrolytic graphite surface as an enzyme substrate: microscopic and spectroscopic studies. Journal of Solid State Electrochemistry 2006, 10, 826-832.
(56) Zhang, L.; Swift, J.; Butts, C. A.; Yerubandi, V.; Dmochowski, I. J. Structure and activity of apoferritin-stabilized gold nanoparticles. Journal of Inorganic Biochemistry 2007, 101, 1719-1729.
(57) Kutin, Y.; Cox, N.; Lubitz, W.; Schnegg, A.; Rudiger, O. In Situ EPR Characterization of a Cobalt Oxide Water Oxidation Catalyst at Neutral pH. Catalysts 2019, 9, 926.
(58) Moura, I. et. al. J. Inorg. Biochem, 1991, 44, 2, 127-139.
(59) Slater, et. al. J. Phys. Chem. Lett, 2015, 6, 18, 3731-3736.
(60) Laursen, B. W., Krebs, F. C., Eur. J. Chem., 2001, 7, 8, 1773-1783.
(61) Brill, A. R., et. al. J. Mater. Chem. C, 2021,9, 11569-11587.
(62) Trevino, R. E.; et. al. ACS Appl. Energy Mater. 2020, 3, 11, 11099-11112.

The compounds, compositions, and methods of the appended claims are not limited in scope by the specific compounds, compositions, and methods described herein, which are intended as illustrations of a few aspects of the claims. Any compounds, compositions, and methods that are functionally equivalent are intended to fall within the scope of the claims. Various modifications of the compounds, compositions, and methods in addition to those shown and described herein are intended to fall within the scope of the appended claims. Further, while only certain representative compounds, components, compositions, and method steps disclosed herein are specifically described, other combinations of the compounds, components, compositions, and method steps also are intended to fall within the scope of the appended claims, even if not specifically recited. Thus, a combination of steps, elements, components, or constituents may be explicitly mentioned herein or less, however, other combinations of steps, elements, components, and constituents are included, even though not explicitly stated.

The term “comprising” and variations thereof as used herein is used synonymously with the term “including” and variations thereof and are open, non-limiting terms. Although the terms “comprising” and “including” have been used herein to describe various embodiments, the terms “consisting essentially of” and “consisting of” can be used in place of “comprising” and “including” to provide for more specific embodiments of the invention and are also disclosed. Other than where noted, all numbers expressing geometries, dimensions, and so forth used in the specification and claims are to be understood at the very least, and not as an attempt to limit the application of the doctrine of equivalents to the scope of the claims, to be construed in light of the number of significant digits and ordinary rounding approaches.

Unless defined otherwise, all technical and scientific terms used herein have the same meanings as commonly understood by one of skill in the art to which the disclosed invention belongs. Publications cited herein and the materials for which they are cited are specifically incorporated by reference.

What is claimed is:

1. A metal-substituted rubredoxin polypeptide comprising a non-native metal bound within a coordination environment of the rubredoxin polypeptide.

2. The polypeptide of claim 1, wherein the non-native metal is not Ni, Co, Zn, Cd, Hg, Ga, Cu, or Mo.

3. The polypeptide of any of claims 1-2, wherein the rubredoxin polypeptide comprises a naturally-occurring rubredoxin polypeptide.

4. The polypeptide of any of claims 1-3, wherein the rubredoxin polypeptide comprises an amino acid sequence of a rubredoxin from Desulfovibrio vulgaris.

5. The polypeptide of any of claims 1-2, wherein the rubredoxin polypeptide comprises a biologically active analogue, fragment, or modifications of a naturally occurring rubredoxin protein.

6. The polypeptide of any of claims 1-5, wherein the coordination environment comprises a tetradentate coordination environment.

7. The polypeptide of any of claims 1-6, wherein the coordination environment comprises a tetrathiolate coordination environment.

8. The polypeptide of any of claims 1-7, wherein the coordination environment is formed by four cysteine residues present in the rubredoxin polypeptide.

9. The polypeptide of any of claims 1-7, wherein the coordination environment is formed by one or more cysteine residues and one or more histidine residues present in the rubredoxin polypeptide.

10. The polypeptide of any of claims 1-7, wherein the coordination environment is formed by three cysteine residues and one histidine residue present in the rubredoxin polypeptide.

11. The polypeptide of any of claims 1-7, wherein the coordination environment is formed by two cysteine residues and two histidine residues present in the rubredoxin polypeptide.

12. The polypeptide of any of claims 1-7, wherein the coordination environment is formed by one cysteine residue and three histidine residues present in the rubredoxin polypeptide.

13. The polypeptide of any of claims 1-7, wherein the coordination environment is formed by four histidine residues present in the rubredoxin polypeptide.

14. The polypeptide of any of claims 1-7, wherein the coordination environment is formed by one or more cysteine residues and one or more aspartic acid residues present in the rubredoxin polypeptide.

15. The polypeptide of any of claims 1-7, wherein the coordination environment is formed by three cysteine residues and one aspartic acid residue present in the rubredoxin polypeptide.

16. The polypeptide of any of claims 1-7, wherein the coordination environment is formed by two cysteine residues and two aspartic acid residues present in the rubredoxin polypeptide.

17. The polypeptide of any of claims 1-7, wherein the coordination environment is formed by one cysteine residue and three aspartic acid residues present in the rubredoxin polypeptide.

18. The polypeptide of any of claims 1-7, wherein the coordination environment is formed by four aspartic acid residues present in the rubredoxin polypeptide.

19. The polypeptide of any of claims 1-7, wherein the coordination environment is formed by one or more cysteine residues and one or more glutamic acid residues present in the rubredoxin polypeptide.

20. The polypeptide of any of claims 1-7, wherein the coordination environment is formed by three cysteine residues and one glutamic acid residue present in the rubredoxin polypeptide.

21. The polypeptide of any of claims 1-7, wherein the coordination environment is formed by two cysteine residues and two glutamic acid residues present in the rubredoxin polypeptide.

22. The polypeptide of any of claims 1-7, wherein the coordination environment is formed by one cysteine residue and three glutamic acid residues present in the rubredoxin polypeptide.

23. The polypeptide of any of claims 1-7, wherein the coordination environment is formed by glutamic aspartic acid residues present in the rubredoxin polypeptide.

24. The polypeptide of any of claims 1-7, wherein the coordination environment is formed by one or more cysteine residues and one or more serine residues present in the rubredoxin polypeptide.

25. The polypeptide of any of claims 1-7, wherein the coordination environment is formed by three cysteine residues and one serine residue present in the rubredoxin polypeptide.

26. The polypeptide of any of claims 1-7, wherein the coordination environment is formed by two cysteine residues and two serine residues present in the rubredoxin polypeptide.

27. The polypeptide of any of claims 1-7, wherein the coordination environment is formed by one cysteine residue and three serine residues present in the rubredoxin polypeptide.

28. The polypeptide of any of claims 1-7, wherein the coordination environment is formed by four serine residues present in the rubredoxin polypeptide.

29. The polypeptide of any of claims 1-7, wherein the coordination environment is formed by one or more cysteine residues and one or more alanine residues present in the rubredoxin polypeptide.

30. The polypeptide of any of claims 1-7, wherein the coordination environment is formed by three cysteine residues and one alanine residue present in the rubredoxin polypeptide.

31. The polypeptide of any of claims 1-7, wherein the coordination environment is formed by two cysteine residues and two alanine residues present in the rubredoxin polypeptide.

32. The polypeptide of any of claims 1-7, wherein the coordination environment is formed by one cysteine residue and three alanine residues present in the rubredoxin polypeptide.

33. The polypeptide of any of claims 1-7, wherein the coordination environment is formed by four alanine residues present in the rubredoxin polypeptide.

34. The polypeptide of any of claims 1-7, wherein the coordination environment is formed by four amino acid residues present in the rubredoxin polypeptide, wherein each of the four amino acid residues is individually selected from the group consisting of a cysteine residue, a histidine residue, an aspartic acid residue, a glutamic acid residue, a serine residue, and an alanine residue.

35. The polypeptide of claim 34, wherein at least one of the four amino acid residues comprises a cysteine residue.

36. The polypeptide of claim 34, wherein at least two of the four amino acid residues comprise a cysteine residue.

37. The polypeptide of claim 34, wherein at least three of the four amino acid residues comprise a cysteine residue.

38. The polypeptide of any of claims 1-37, wherein the rubredoxin polypeptide comprises a polypeptide having at least 70%, at least 75%, at least 80%, at least 85%, at least 90%, or at least 95% homology to any one of SEQ. ID 1-SEQ. ID 105.

39. The polypeptide of any of claims 1-38, wherein the rubredoxin polypeptide comprises a polypeptide of any one of SEQ. ID 1-SEQ. ID 105.

40. The polypeptide of any of claims 1-39, wherein the non-native metal bound within the coordination environment comprises a low spin metal complex.

41. The polypeptide of any of claims 1-40, wherein the non-native metal is cobalt.

42. The polypeptide of any of claims 1-40, wherein the non-native metal is titanium.

43. The polypeptide of any of claims 1-40, wherein the non-native metal is manganese.

44. The polypeptide of any of claims 1-40, wherein the non-native metal is molybdenum.

45. The polypeptide of claim 44, wherein the metal-substituted rubredoxin polypeptide comprises Mo(V)-rubredoxin.

46. The polypeptide of any of claims 1-40, wherein the non-native metal is vanadium.

47. The polypeptide of claim 46, wherein the metal-substituted rubredoxin polypeptide comprises vanadyl-rubredoxin ((V═O)-rubredoxin).

48. The polypeptide of any of claims 1-47, wherein the metal-substituted rubredoxin polypeptide is stable up to at least 77 K, as indicated by continuous-wave electron paramagnetic resonance (cwEPR).

49. The polypeptide of any of claims 1-48, wherein the metal-substituted rubredoxin polypeptide is immobilized on a surface.

50. The polypeptide of any of claims 1-49, wherein the metal-substituted rubredoxin polypeptide is covalently attached to a triazatriangulene.

51. The polypeptide of any of claims 1-50, wherein the metal-substituted rubredoxin polypeptide is covalently attached to a surface.

52. The polypeptide of any of claims 49-51, wherein the surface comprises a semiconductor surface.

53. A system comprising a periodic array of the polypeptides of any of claims 1-48 immobilized on a surface.

54. The system of claim 53, wherein the polypeptides are covalently attached to the surface.

55. The system of any of claims 53-54, wherein the surface comprises a semiconductor surface.

56. The system of any of claims 53-55, wherein the surface comprises graphene.

57. The system of any of claims 53-56, wherein the surface comprises graphene-MoS₂.

58. A quantum information processing platform comprising a metal-substituted metalloprotein comprising a non-native metal bound within a coordination environment of the metalloprotein.

59. The platform of claim 58, wherein the metalloprotein is azurin, hemoglobin, myoglobin, hemerythrin, cytochrome, iron-sulfur protein, rubredoxin, plastocyanin, ferritin, ceruloplasmin, carbonic anhydrase, vitamin B₁₂-dependent enzyme, nitrogenase, superoxide dismutase, chlorophyll-containing protein, calmoduline, glucose-6-phosphatase, hexokinase, DNA polymerase, vanabin, arginase, catalase, hydrogenase, iron-responsive element binding protein, aconitase, urease, cytochrome oxidase, laccase, alcohol dehydrogenase, carboxy peptidase, amino peptides, β-amyloid protein, nitrate reductase, glutathione peroxidase, metallothionein, R2-like ligand binding oxidase, or a phosphatase.

60. The platform of any of claims 58-59, wherein the metalloprotein comprises azurin.

61. The platform of any of claims 58-59, wherein the metalloprotein comprises hemoglobin.

62. The platform of any of claims 58-59, wherein the metalloprotein comprises myoglobin.

63. The platform of any of claims 58-59, wherein the metalloprotein comprises rubredoxin.

64. The platform of any of claims 58-59, wherein the metalloprotein comprises R2-like ligand binding oxidase.

65. The platform of any of claims 58-64, wherein the non-native metal bound within the coordination environment comprises a low spin metal complex.

66. The platform of any of claims 58-65, wherein the non-native metal is cobalt.

67. The platform of any of claims 58-65, wherein the non-native metal is titanium.

68. The platform of any of claims 58-65, wherein the non-native metal is manganese.

69. The platform of any of claims 58-65, wherein the non-native metal is molybdenum.

70. The platform of claim 69, wherein the non-native metal comprises Mo(V).

71. The platform of any of claims 58-65, wherein the non-native metal is vanadium.

72. The platform of claim 71, wherein the non-native metal comprises V(IV).

73. The platform of any of claims 58-72, wherein the metal-substituted metalloprotein is stable up to at least 77 K, as indicated by continuous-wave electron paramagnetic resonance (cwEPR).

74. The platform of any of claims 58-73, wherein the metal-substituted metalloprotein comprises a polypeptide of any of claims 1-48.
